(19) United States
(12) Patent Application Publication
(10) Pub. No.: US 2026/0339212 A1
(43) Pub. Date: Oct. 29, 2026

(54) RESIST UNDERLAYER FILM-FORMING COMPOSITION

(71) Applicant: NISSAN CHEMICAL CORPORATION, Tokyo (JP)

(72) Inventors: Shun KUBODERA, Toyama-shi (JP); Tokio NISHITA, Toyama-shi (JP)

(73) Assignee: NISSAN CHEMICAL CORPORATION, Tokyo (JP)

(21) Appl. No.: 18/998,750

(22) PCT Filed: Jul. 11, 2023
(86) PCT No.: PCT/JP2023/025533

§ 371 Date: Jan. 27, 2025

(30) Foreign Application Priority Data
Jul. 29, 2022 (JP) 2022-121139

(51) Int. Cl. G03F 7/11; G03F 7/038; G03F 7/20; H10P 14/68; H10P 50/00; H10P 76/20

(52) U.S. Cl. CPC G03F 7/11; G03F 7/038; G03F 7/2006; H10P 14/687; H10P 50/73; H10P 76/2042; H10P 76/2043

(57) ABSTRACT

A resist underlayer film-forming composition includes: a polymer having an alicyclic structure in a portion other than a terminal; and a solvent.

### TECHNICAL FIELD

The present invention relates to a resist underlayer film-forming composition, a resist underlayer film, a semiconductor processing substrate, a method of manufacturing a semiconductor element, and a method of forming a pattern.

### BACKGROUND ART

In manufacture of a semiconductor device, micromachining by lithography has been conventionally performed using a photoresist composition. The micromachining is a processing method in which a thin film of a photoresist composition is formed on a silicon wafer, irradiated with an active energy ray such as an ultraviolet ray through a mask pattern on which a pattern of a semiconductor device is drawn, and developed and the silicon wafer is etched using the obtained resist pattern as a protective film.

However, in recent years, the degree of integration in a semiconductor device has been increased and the wavelength of the active energy ray to be used tends to shortened from the wavelength by a KrF excimer laser (248 nm) to the wavelength by an ArF excimer laser (193 nm). As a result, the influence of diffuse reflection of an active energy ray from a substrate and a standing wave has become a major problem. Then, a method of providing a bottom anti-reflective coating (BARC), which is a resist underlayer film, between a photoresist and a substrate has been widely studied.

For example, the present applicant has proposed a composition, for formation of a resist underlayer film for lithography, containing a polymer having a main chain including a sulfur atom, and containing a solvent (see Patent Literature 1).

### CITATION LIST

### Patent Literature

Patent Literature 1: JP 2013-033276 A

### SUMMARY OF INVENTION

### Technical Problem

A lithography defect due to resist pattern collapse accompanying miniaturization of a resist pattern has become a problem.

Therefore, an object of the present invention is to provide a resist underlayer film-forming composition, a resist underlayer film, a semiconductor processing substrate, a method of manufacturing a semiconductor element, and a method of forming a pattern that are capable of suppressing resist pattern collapse.

### Solution to Problem

As a result of intensive studies to solve the above problem, the present inventors have found that the above problem can be solved, and have completed the present invention having the following gist.

That is, the present invention includes the following.

[1]A resist underlayer film-forming composition including: a polymer having an alicyclic structure in a portion other than a terminal; and a solvent.

[2] The resist underlayer film-forming composition according to [1], wherein the polymer further has an aromatic hydrocarbon ring.

[3] The resist underlayer film-forming composition according to [1] or [2], wherein the polymer further has a nitrogen-containing ring.

[4] The resist underlayer film-forming composition according to any one of [1] to [3], wherein the polymer has a structure having the alicyclic structure, the structure represented by Formula (1) described below:

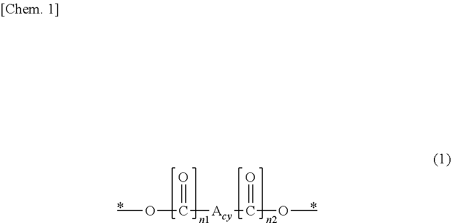

wherein A_{cy} represents a divalent group having the alicyclic structure, n1 and n2 each independently represent 0 or 1, and * represents a bond.

[5] The resist underlayer film-forming composition according to any one of [2] to [4], wherein the polymer has a structure having the aromatic hydrocarbon ring, the structure represented by Formula (2) described below:

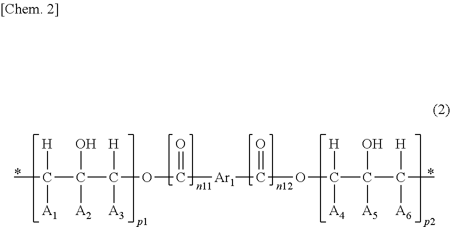

wherein A_{cy} represents a divalent organic group having the aromatic hydrocarbon ring, n1 and n12 each independently represent 0 or 1, p1 and p2 each independently represent 0 or 1, A₁, A₂, A₃, A₄, A₅, and A₆ each independently represent a hydrogen atom, a methyl group, or an ethyl group, and * represents a bond.

[6] The resist underlayer film-forming composition according to any one of [3] to [5], wherein the polymer has a structure having the nitrogen-containing ring, the structure represented by Formula (3) described below:

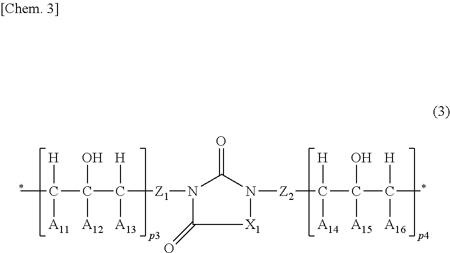

wherein X₁ represents a group represented by any one of Formulas (3-1) to (3-3) described below:

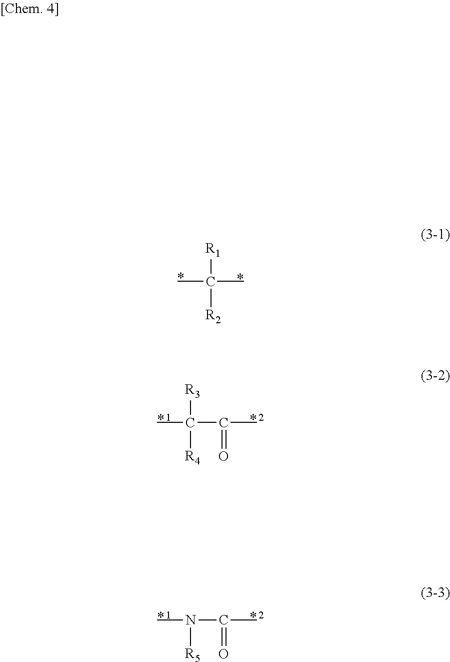

wherein R₁ to R₅ each independently represent a hydrogen atom, an alkyl group having 1 to 10 carbon atoms that are optionally interrupted by an oxygen atom or a sulfur atom, an alkenyl group having 2 to 10 carbon atoms that are optionally interrupted by an oxygen atom or a sulfur atom, an alkynyl group having 2 to 10 carbon atoms that are optionally interrupted by an oxygen atom or a sulfur atom, a benzyl group, or a phenyl group, and the phenyl group is optionally substituted with at least one monovalent group selected from the group consisting of alkyl groups having 1 to 6 carbon atoms, halogen atoms, alkoxy groups having 1 to 6 carbon atoms, a nitro group, a cyano group, and alkylthio groups having 1 to 6 carbon atoms,
R₁ and R₂ are optionally bonded to each other to form a ring having 3 to 6 carbon atoms,
R₃ and R₄ are optionally bonded to each other to form a ring having 3 to 6 carbon atoms,
* represents a bond, *1 represents a bond to a carbon atom in Formula (3), and *2 represents a bond to a nitrogen atom in Formula (3),
Z₁ and Z₂ each independently represent a single bond or a divalent group represented by Formula (3-4) described below:

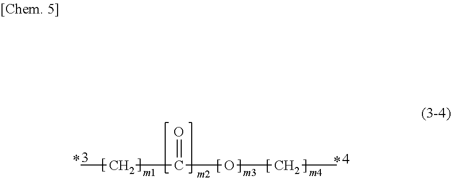

wherein m1 is an integer of 0 to 4, m2 is 0 or 1, m3 is 0 or 1, and m4 is an integer of 0 to 2 while m1 and m2 are not simultaneously 0 in a case where m3 is 1, *3 represents a bond to a nitrogen atom in Formula (3), and *4 represents a bond,
A₁₁, A₁₂, A₁₃, A₁₄, A₁₅, and A₁₆ each independently represent a hydrogen atom, a methyl group, or an ethyl group, p3 and p4 each independently represent 0 or 1, and represents a bond.

[7] The resist underlayer film-forming composition according to any one of [1] to [6], further including a crosslinking agent.

[8] The resist underlayer film-forming composition according to any one of [1] to [7], further including a curing catalyst.

[9] The resist underlayer film-forming composition according to any one of [1] to [8], being a resist underlayer film-forming composition for formation of an underlayer of a negative photoresist.

[10] The resist underlayer film-forming composition according to any one of [1] to [9], being a resist underlayer film-forming composition for photolithography using an ArF excimer laser or extreme ultraviolet (EUV).

[11]A resist underlayer film consisting of a cured product of the resist underlayer film-forming composition according to any one of [1] to [10].

[12]A semiconductor processing substrate including: a semiconductor substrate; and the resist underlayer film according to [11].

[13]A method of manufacturing a semiconductor element, the method including the steps of:
forming a resist underlayer film on a semiconductor substrate using the resist underlayer film-forming composition according to any one of [1] to [10]; and
forming a resist film on the resist underlayer film.

[14]A method of forming a pattern, the method including the steps of:
forming a resist underlayer film on a semiconductor substrate using the resist underlayer film-forming composition according to any one of [1] to [10];
forming a resist film on the resist underlayer film;
irradiating the resist film with light or an electron beam and then developing the resist film to obtain a resist pattern; and
etching the resist underlayer film using the resist pattern as a mask.

### Advantageous Effects of Invention

According to the present invention, it is possible to provide a resist underlayer film-forming composition, a resist underlayer film, a semiconductor processing substrate, a method of manufacturing a semiconductor element, and a method of forming a pattern that are capable of suppressing resist pattern collapse.

### DESCRIPTION OF EMBODIMENTS

### (Resist Underlayer Film-Forming Composition)

The resist underlayer film-forming composition of the present invention includes a polymer and a solvent.

The resist underlayer film-forming composition may include another component.

### <Polymer>

The polymer has an alicyclic structure in a portion other than a terminal.

In the present invention, “having an alicyclic structure in a portion other than a terminal” does not mean having an alicyclic structure only in a portion other than a terminal. Therefore, the polymer may also have an alicyclic structure at a terminal.

In the present invention, the alicyclic structure refers to an alicyclic hydrocarbon structure.

Examples of the alicyclic structure include alicyclic hydrocarbon structures having 4 to 10 carbon atoms. Examples of the alicyclic hydrocarbon structures having 4 to 10 carbon atoms include a cyclobutane ring structure, a cyclopentane ring structure, a cyclohexane ring structure, a cyclohexene ring structure, a dicyclopentanyl ring structure, a dicyclopentenyl ring structure, a norbornane ring structure, a norbornene ring structure, an isobornene ring structure, a bicyclo[2.2.2]octa-2-ene ring structure, and an adamantane ring structure.

The polymer preferably further has an aromatic hydrocarbon ring from the viewpoint of an excellent optical characteristic (n/k). The aromatic hydrocarbon ring may be monocyclic or polycyclic. The aromatic hydrocarbon ring is not particularly limited, and examples of the aromatic hydrocarbon ring include a benzene ring, a naphthalene ring, and an anthracene ring.

The polymer preferably further has a nitrogen-containing ring from the viewpoint of an excellent optical characteristic (n/k) and excellent adhesion to a resist.

The polymer may be a polymer obtained by addition polymerization or a polymer obtained by polycondensation.

### <<Formula (1)>>

The polymer preferably has a structure represented by Formula (1) described below as a structure having the alicyclic structure, from the viewpoint of suitably obtaining an effect of the present invention.

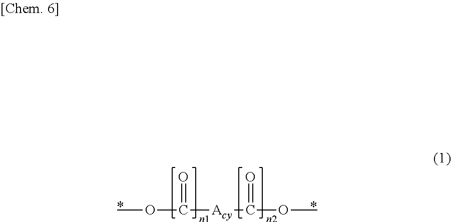

(In Formula (1), A_{cy} represents a divalent group having the alicyclic structure. n1 and n2 each independently represent 0 or 1. * represents a bond.)

The number of carbon atoms of A_{cy} is not particularly limited, and examples of A_{cy} include divalent groups having an alicyclic structure and having 4 to 25 carbon atoms.

Each of the two bonds * in Formula (1) preferably forms a single bond together with one bond * in Formula (2) or (3) described below.

That is, the polymer preferably has at least one of the following structures in which X1 represents the structure represented by Formula (1), X2 represents the structure represented by Formula (2), and X4 represents the structure represented by Formula (3).

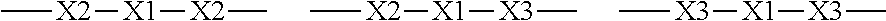

Examples of the structure represented by Formula (1) include the following structures.

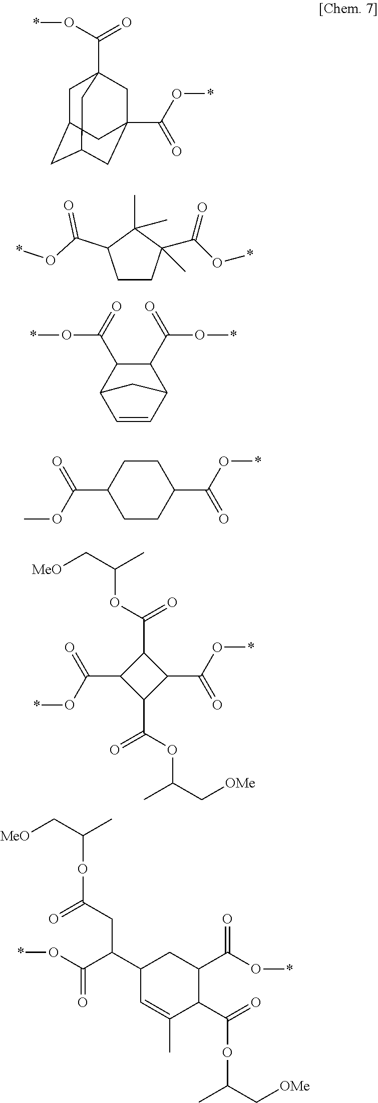

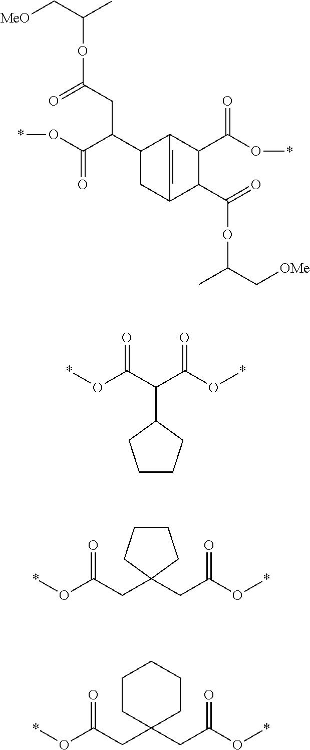

In the above formulas, Me represents a methyl group. * represents a bond.

### <<Formula (2)>>

The polymer preferably has a structure represented by Formula (2) described below as a structure having the aromatic hydrocarbon ring, from the viewpoint of an excellent optical characteristic (n/k).

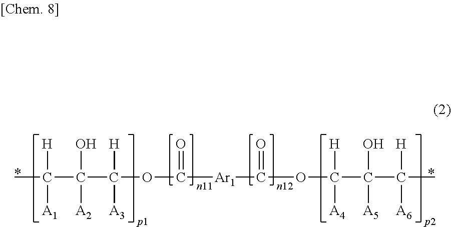

(In Formula (2), Ar₁ represents a divalent organic group having the aromatic hydrocarbon ring. n11 and n12 each independently represent 0 or 1. p1 and p2 each independently represent 0 or 1. A₁, A₂, A₃, A₄, A₅, and A₆ each independently represent a hydrogen atom, a methyl group, or an ethyl group. * represents a bond.)

The number of carbon atoms of the divalent organic group having the aromatic hydrocarbon ring in Ar₁ is not particularly limited, and examples of Ar₁ include divalent organic groups having the aromatic hydrocarbon ring and having 6 to 20 carbon atoms.

Ar₁ represents, for example, a divalent organic group represented by any one of Formulas (2-1) to (2-2) described below:

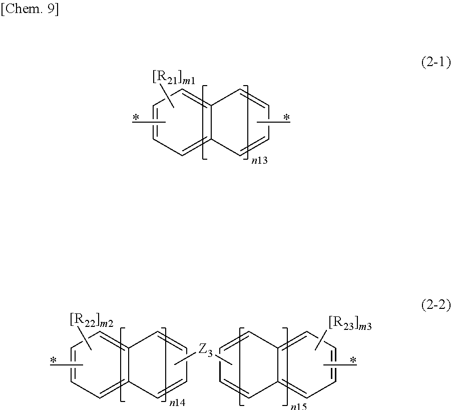

(In Formulas (2-1) to (2-2), R₂₁ to R₂₃ each independently represent a halogen atom, a hydroxy group, an alkyl group having 1 to 6 carbon atoms, an alkenyl group having 2 to 6 carbon atoms, an alkynyl group having 2 to 6 carbon atoms, an alkoxy group having 1 to 6 carbon atoms, an alkenyloxy group having 2 to 6 carbon atoms, an alkynyloxy group having 2 to 6 carbon atoms, an acyl group having 2 to 6 carbon atoms, an aryloxy group having 6 to 12 carbon atoms, an arylcarbonyl group having 7 to 13 carbon atoms, or an aralkyl group having 7 to 13 carbon atoms. * represents a bond.

In Formula (2-1), n13 represents 0 or 1. When n13 is 0, m1 represents an integer of 0 to 4. When n13 is 1, m1 represents an integer of 0 to 6. When the number of R₂₁s is 2 or more, the 2 or more of R₂₁s may be the same or different.

In Formula (2-2), Z₃ represents a single bond, an oxygen atom, a sulfur atom, a carbonyl group, a sulfonyl group, or an alkylene group having 1 to 6 carbon atoms. n14 and n15 each independently represent 0 or 1. When n14 is 0, m2 represents an integer of 0 to 4. When n14 is 1, m2 represents an integer of 0 to 6. When n15 is 0, m3 represents an integer of 0 to 4. When n15 is 1, m3 represents an integer of 0 to 6. When the number of R₂₂s is 2 or more, the 2 or more of R₂₂s may be the same or different. When the number of R₂₃s is 2 or more, the 2 or more of R₂₃s may be the same or different.)

In the present description, examples of a halogen atom include a fluorine atom, a chlorine atom, a bromine atom, and an iodine atom.

In the present description, an alkyl group is not limited to a linear alkyl group, and may be branched or cyclic. Examples of the linear or branched alkyl group include a methyl group, an ethyl group, an isopropyl group, a tert-butyl group, and an n-hexyl group. Examples of the cyclic alkyl group (cycloalkyl group) include a cyclobutyl group, a cyclopentyl group, and a cyclohexyl group.

In the present description, examples of an alkoxy group include a methoxy group, an ethoxy group, an n-pentyloxy group, and an isopropoxy group.

In the present description, examples of an alkylthio group include a methylthio group, an ethylthio group, an n-pentylthio group, and an isopropylthio group.

In the present description, examples of an alkenyl group include an ethenyl group, a 1-propenyl group, a 2-propenyl group, a 1-methyl-1-ethenyl group, a 1-butenyl group, a 2-butenyl group, a 3-butenyl group, a 2-methyl-1-propenyl group, and a 2-methyl-2-propenyl group. In the present description, examples of an alkynyl group include groups in which a double bond of an alkenyl group listed above as an “alkenyl group” is replaced with a triple bond.

In the present description, examples of an alkenyloxy group include a vinyloxy group, a 1-propenyloxy group, a 2-n-propenyloxy group (allyloxy group), a 1-n-butenyloxy group, and a prenyloxy group.

In the present description, examples of an alkynyloxy group include a 2-propynyloxy group, a 1-methyl-2-propynyloxy group, a 2-methyl-2-propynyloxy group, a 2-butynyloxy group, and a 3-butynyloxy group.

In the present description, examples of an acyl group include an acetyl group and a propionyl group.

In the present description, examples of an aryloxy group include a phenoxy group and naphthyloxy.

In the present description, examples of an arylcarbonyl group include a phenylcarbonyl group.

In the present description, examples of an aralkyl group include a benzyl group and a phenethyl group.

In the present description, examples of an alkylene group include a methylene group, an ethylene group, a 1,3-propylene group, a 2,2-propylene group, a 1-methylethylene group, a 1,4-butylene group, a 1-ethylethylene group, a 1-methylpropylene group, a 2-methylpropylene group, a 1,5-pentylene group, a 1-methylbutylene group, a 2-methylbutylene group, a 1,1-dimethylpropylene group, a 1,2-dimethylpropylene group, a 1-ethylpropylene group, a 2-ethylpropylene group, a 1,6-hexylene group, a 1,4-cyclohexylene group, a 1,8-octylene group, a 2-ethyloctylene group, a 1,9-nonylene group, and a 1,10-decylene group.

Examples of the structure represented by Formula (2X) described below in Formula (2) include the following structures.

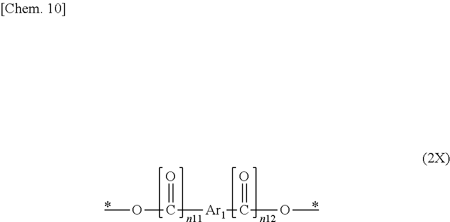

(In Formula (2X), Ar₁, n11, and n12 have the same meanings as Ar₁, n11, and n12 in Formula (2), respectively. * represents a bond.)

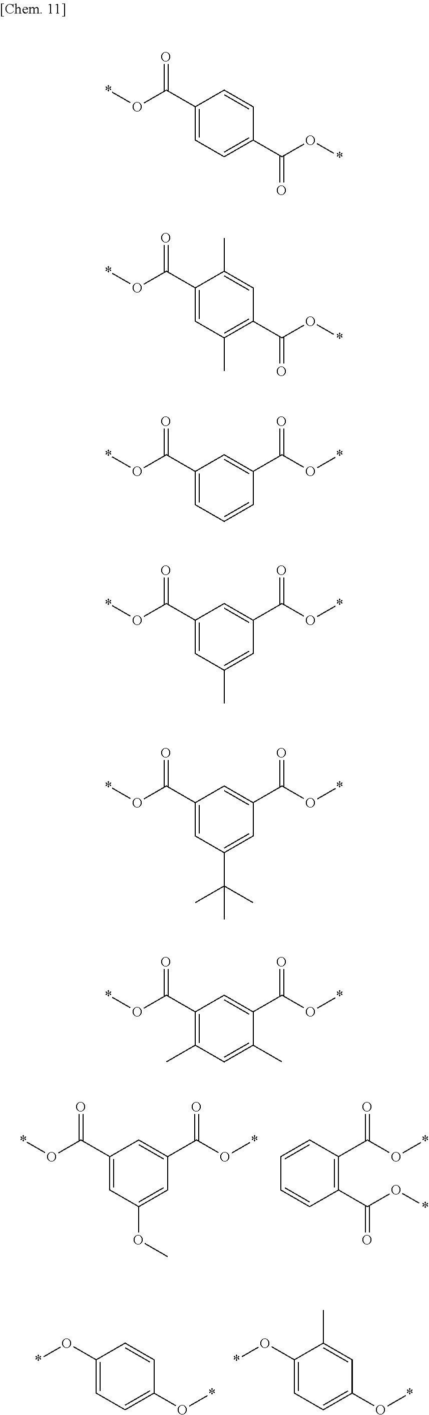

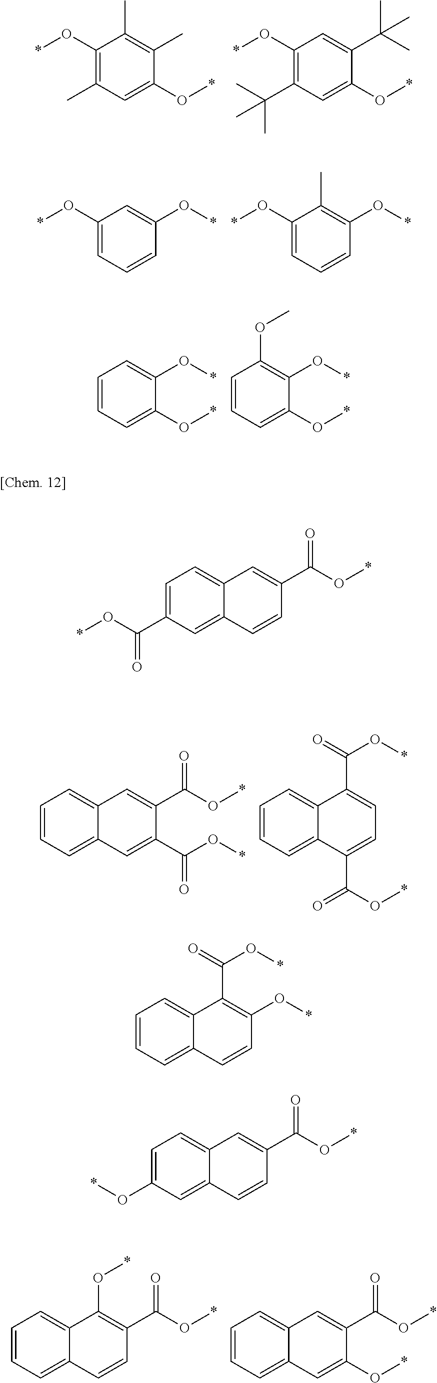

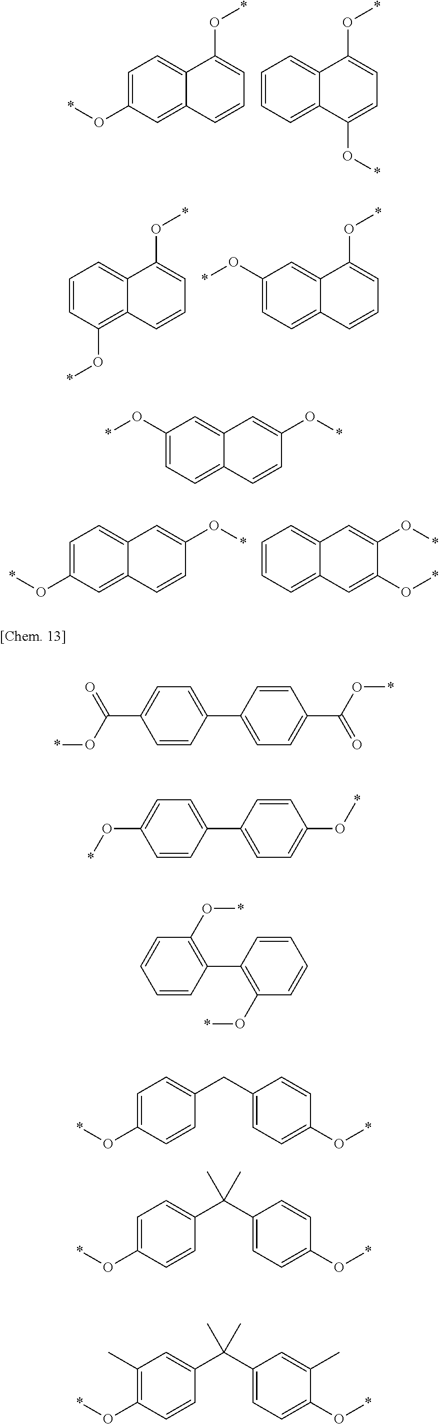

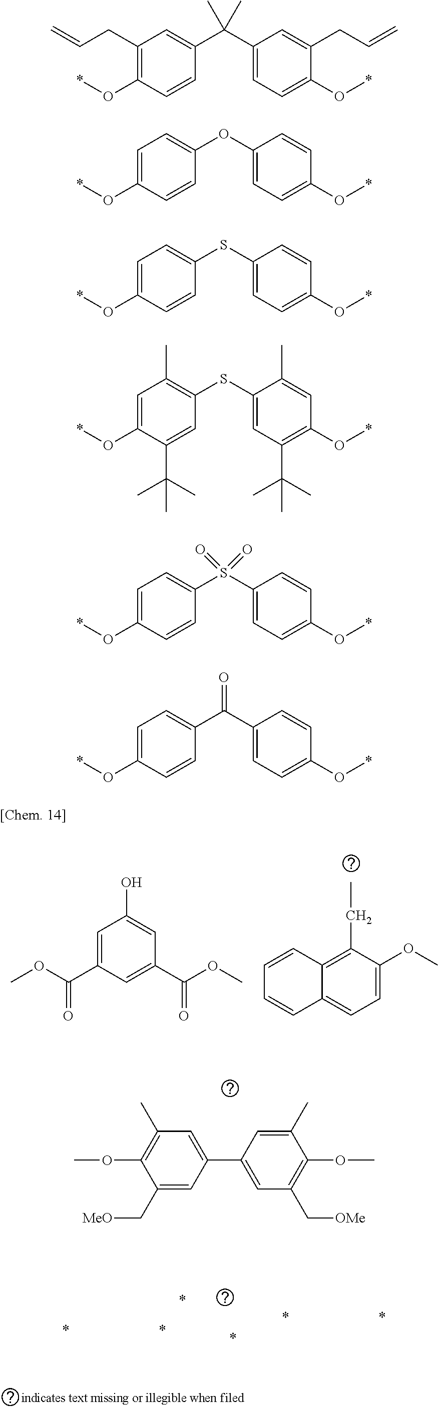

In the above formulas, Me represents a methyl group. * represents a bond.

### <<Formula (3)>>

The polymer preferably has a structure represented by Formula (3) described below as a structure having the nitrogen-containing ring, from the viewpoint of an excellent optical characteristic (n/k) and excellent adhesion to a resist.

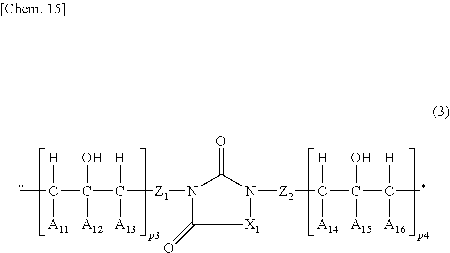

(In Formula (3), X₁ represents a group represented by any one of Formulas (3-1) to (3-3) described below. Z₁ and Z₂ each independently represent a single bond or a divalent group represented by Formula (3-4) described below. A₁₁, A₁₂, A₁₃, A₁₄, A₁₅, and A₁₆ each independently represent a hydrogen atom, a methyl group, or an ethyl group. p3 and p4 each independently represent 0 or 1. * represents a bond.)

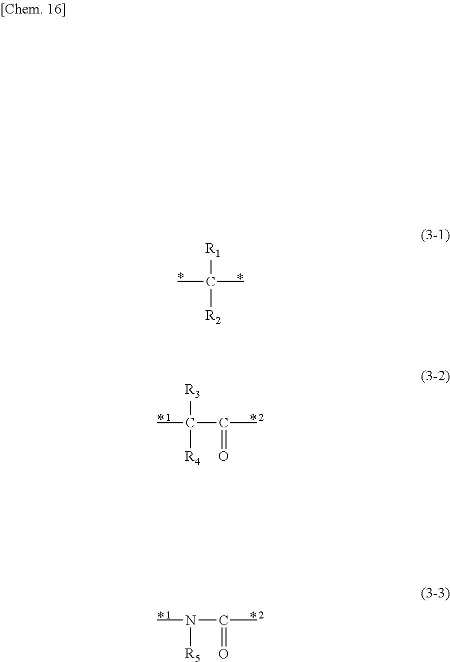

(In Formulas (3-1) to (3-3), R₁ to R₅ each independently represent a hydrogen atom, an alkyl group having 1 to 10 carbon atoms that are optionally interrupted by an oxygen atom or a sulfur atom, an alkenyl group having 2 to 10 carbon atoms that are optionally interrupted by an oxygen atom or a sulfur atom, an alkynyl group having 2 to 10 carbon atoms that are optionally interrupted by an oxygen atom or a sulfur atom, a benzyl group, or a phenyl group, and the phenyl group is optionally substituted with at least one monovalent group selected from the group consisting of alkyl groups having 1 to 6 carbon atoms, halogen atoms, alkoxy groups having 1 to 6 carbon atoms, a nitro group, a cyano group, and alkylthio groups having 1 to 6 carbon atoms.

R₁ and R₂ are optionally bonded to each other to form a ring having 3 to 6 carbon atoms.

R₃ and R₄ are optionally bonded to each other to form a ring having 3 to 6 carbon atoms. * represents a bond. *1 represents a bond to a carbon atom in Formula (3). *2 represents a bond to a nitrogen atom in Formula (3).)

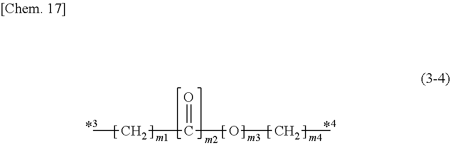

(In Formula (3-4), m1 is an integer of 0 to 4, m2 is 0 or 1, m3 is 0 or 1, and m4 is an integer of 0 to 2. Here, in a case where m3 is 1, m1 and m2 are not simultaneously 0. *3 represents a bond to a nitrogen atom in Formula (3). *4 represents a bond.)

Examples of the alkyl group having 1 to 10 carbon atoms that are optionally interrupted by an oxygen atom or a sulfur atom in R₁ to R₅ in Formulas (3-1) to (3-3) include alkyl groups having 1 to 10 carbon atoms, alkoxy groups having 1 to 10 carbon atoms, alkoxyalkyl groups having 2 to 10 carbon atoms, alkoxyalkoxyalkyl groups having 3 to 10 carbon atoms, alkylthio groups having 1 to 10 carbon atoms, and alkylthioalkyl groups having 2 to 10 carbon atoms.

The alkyl group having 1 to 10 carbon atoms that are optionally interrupted by an oxygen atom or a sulfur atom may contain two or more oxygen atoms or sulfur atoms.

Examples of the structure represented by Formula (3X) described below in Formula (3) include the following structures.

Here, in a case where Formula (3X) represents a hydantoin structure, two or more different hydantoin structures are preferably not included in the polymer structure.

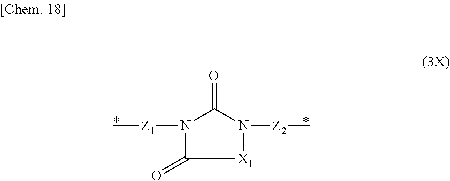

(In Formula (3X), X₁, Z₁, and Z₂ have the same meanings as X₁, Z₁, and Z₂ in Formula (3), respectively. * represents a bond.)

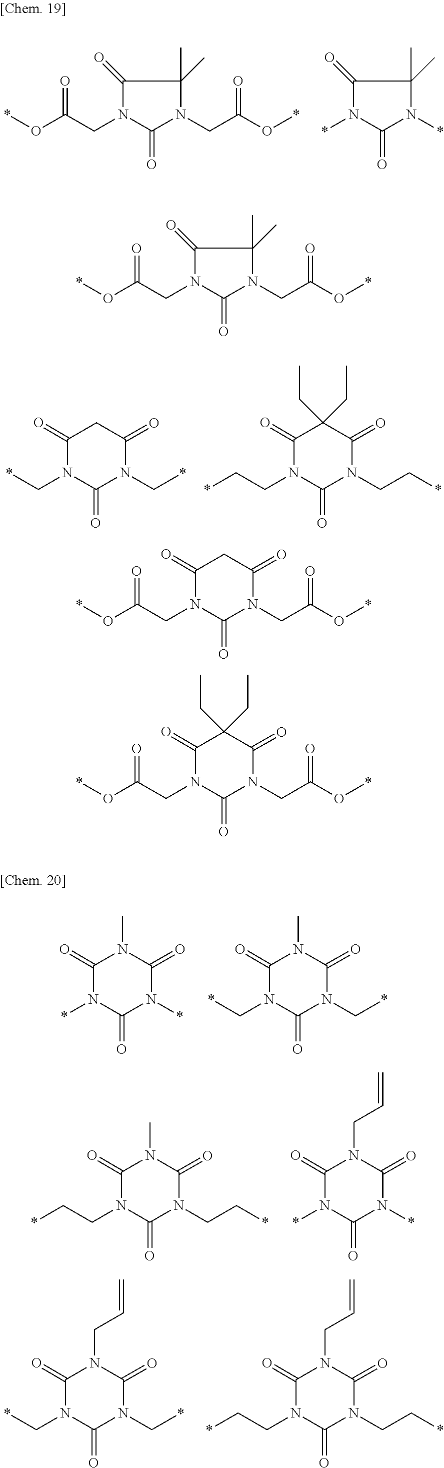

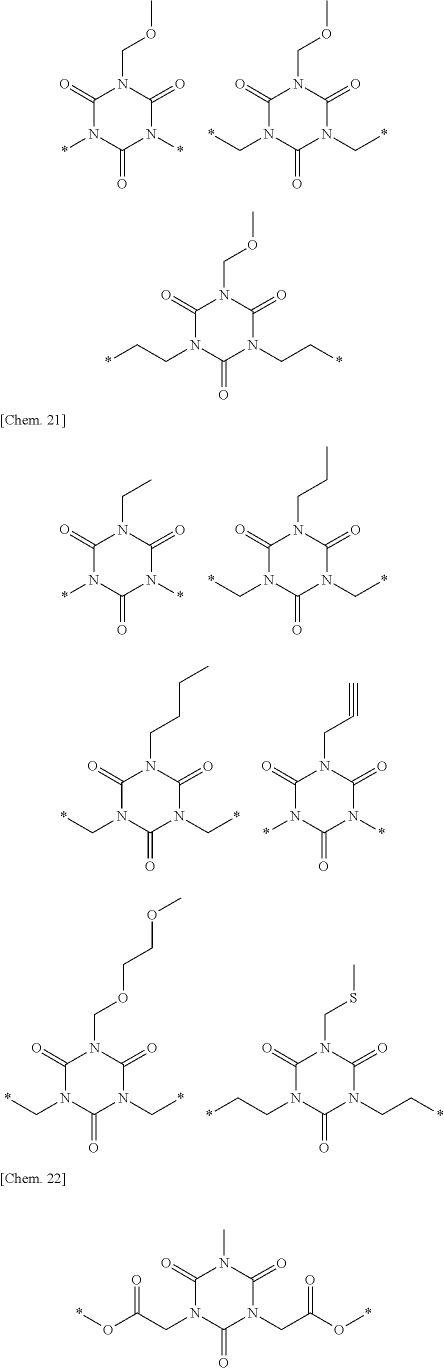

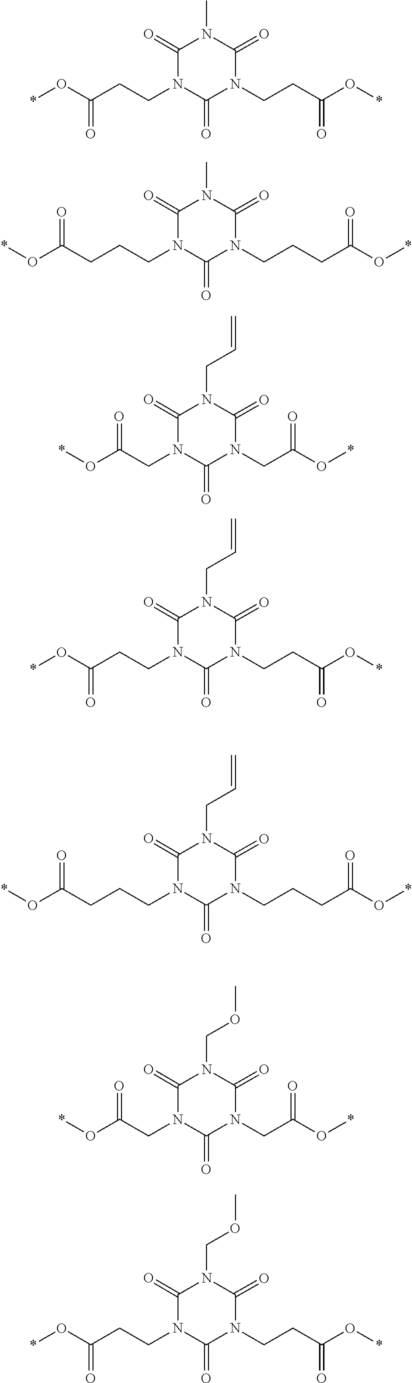

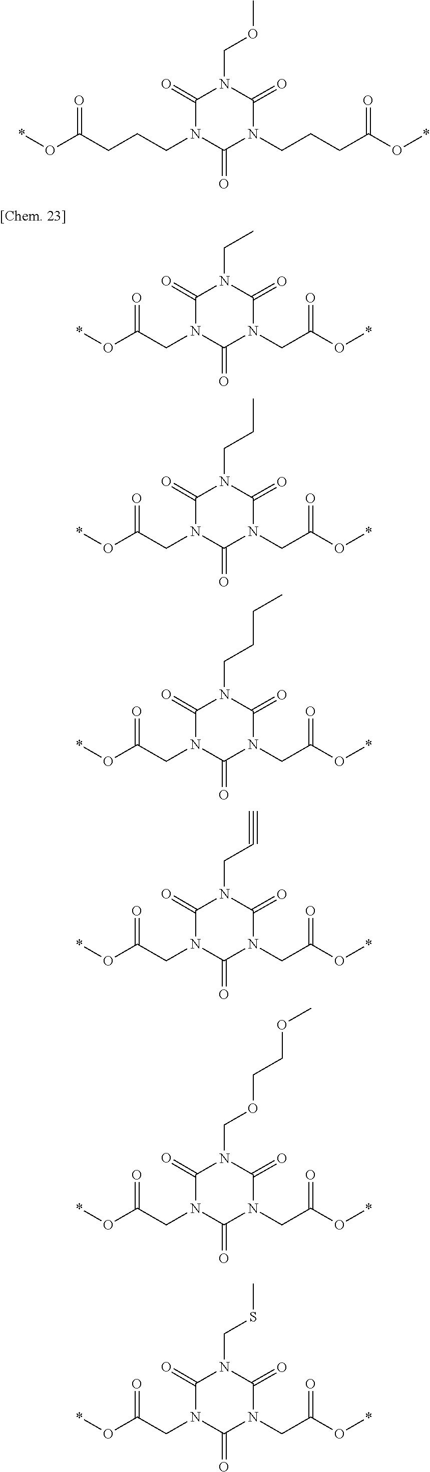

In the above formulas, * represents a bond.

The polymer is, for example, not a reaction product of a hydantoin-containing compound (A) having two epoxy groups and a hydantoin-containing compound (B) different from the hydantoin-containing compound (A).

Examples of the polymer include polymers having the following structures.

### Polymer Specific Example 1

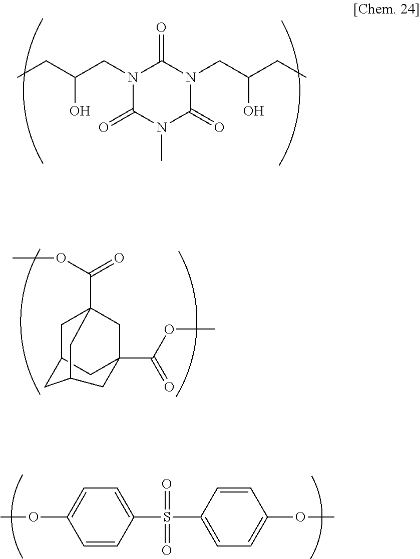

### Polymer Specific Example 2

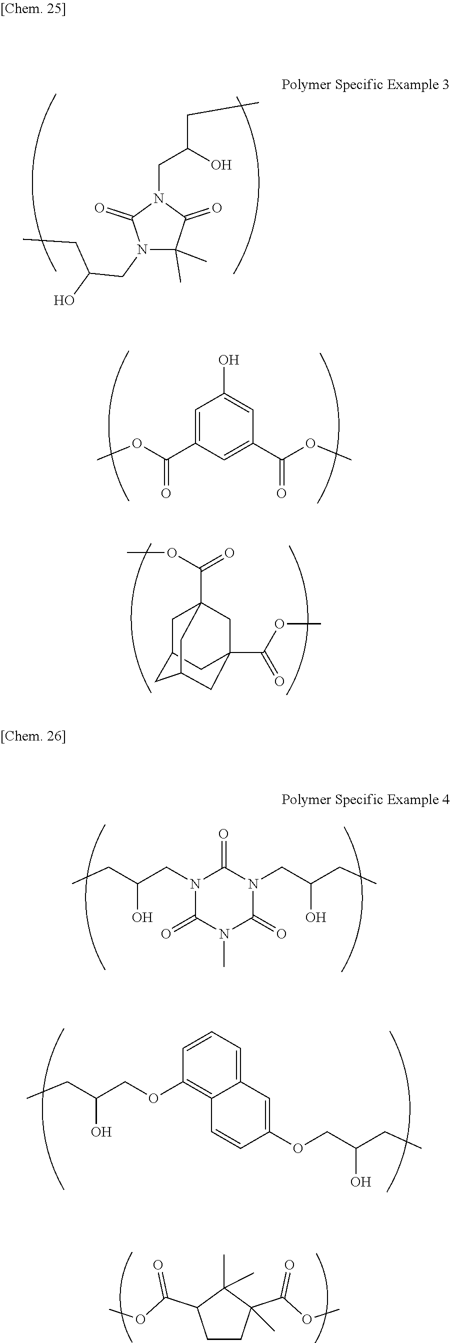

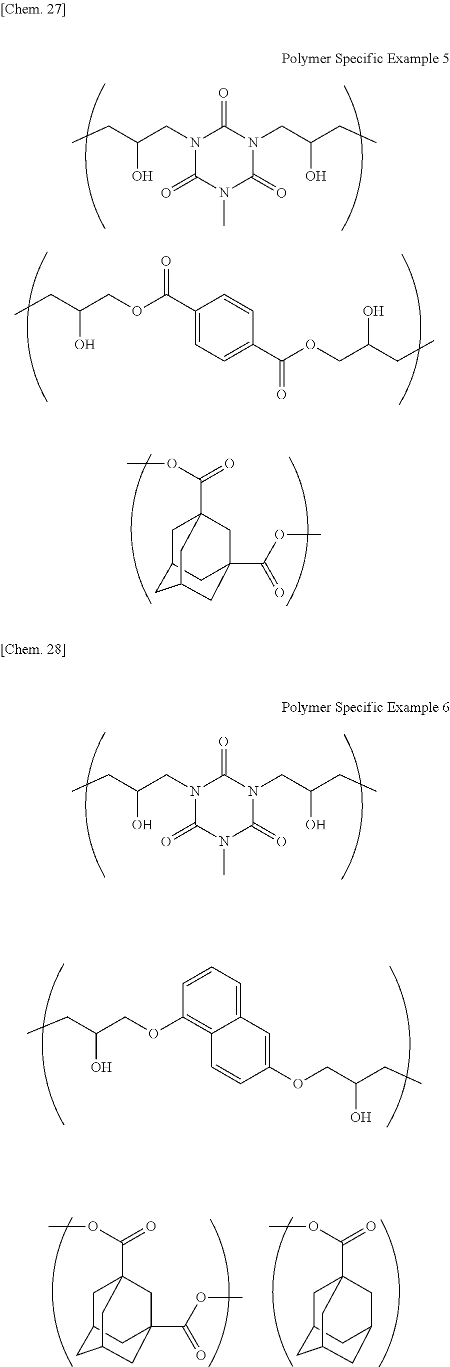

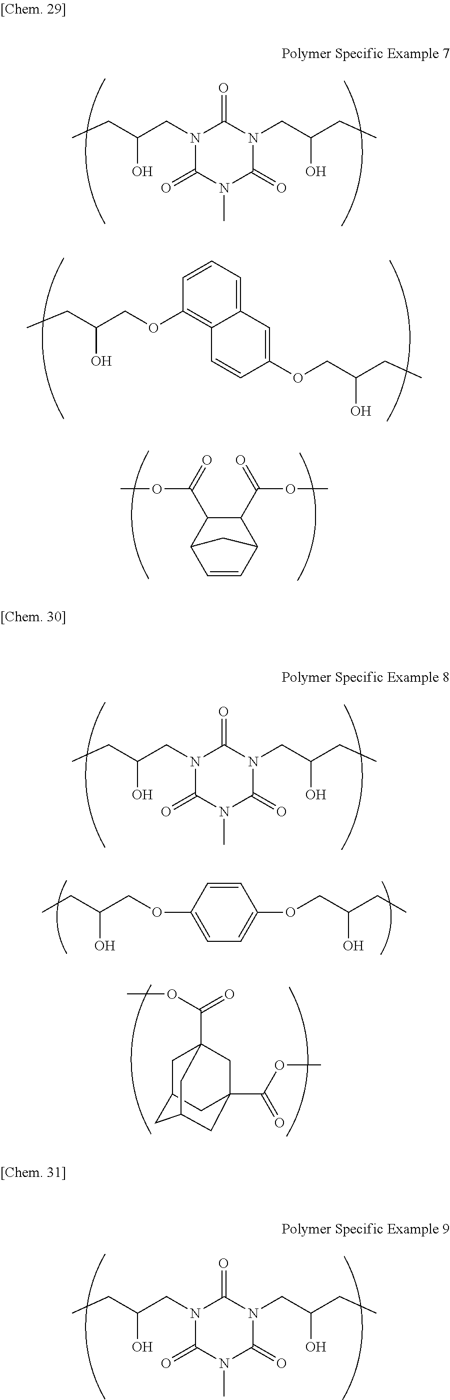

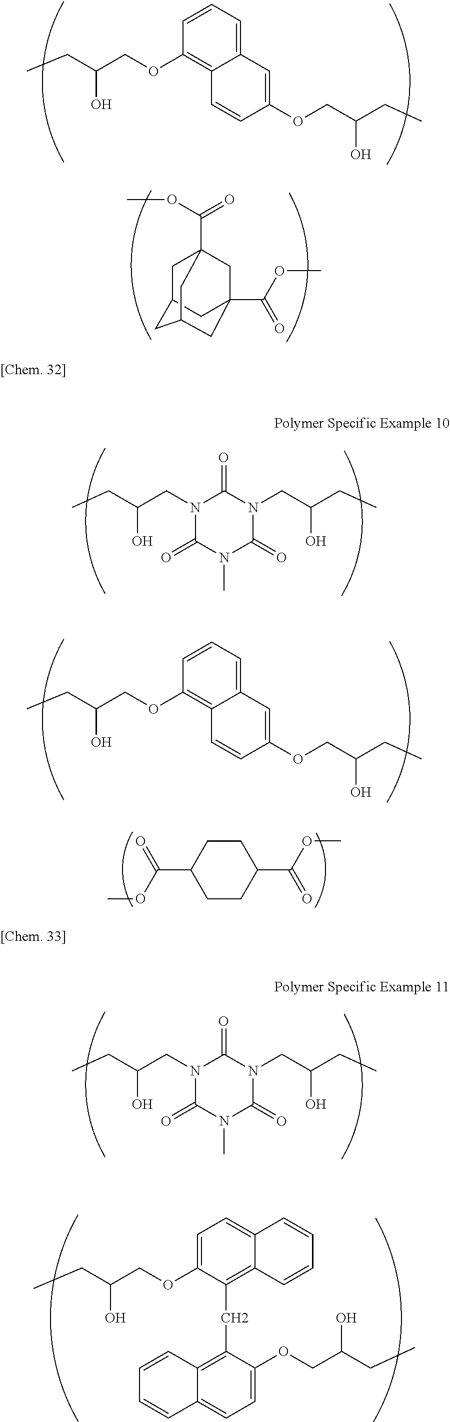

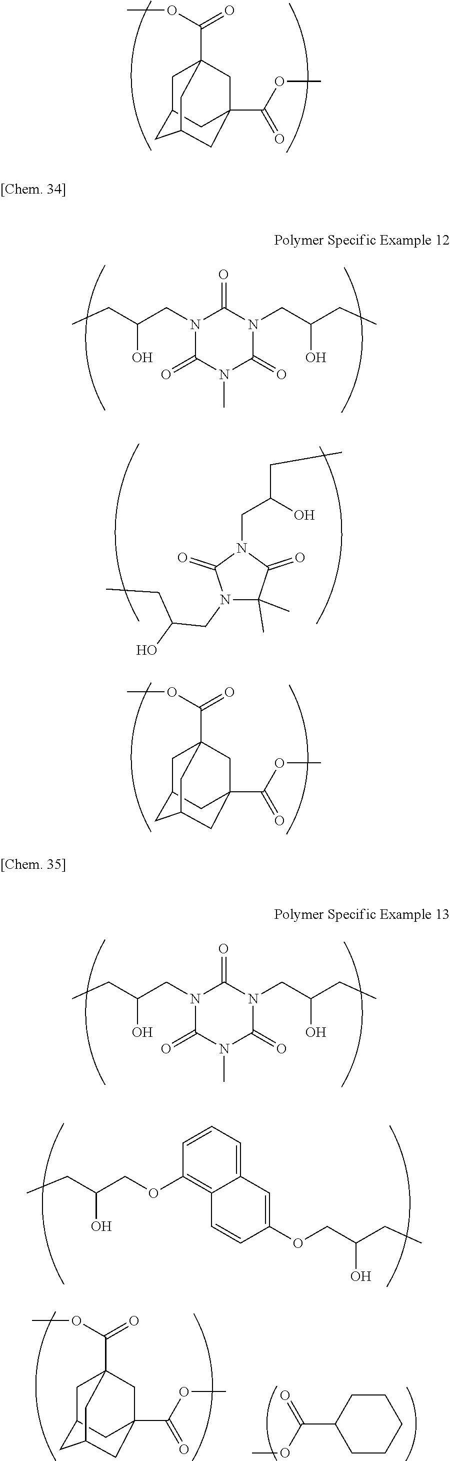

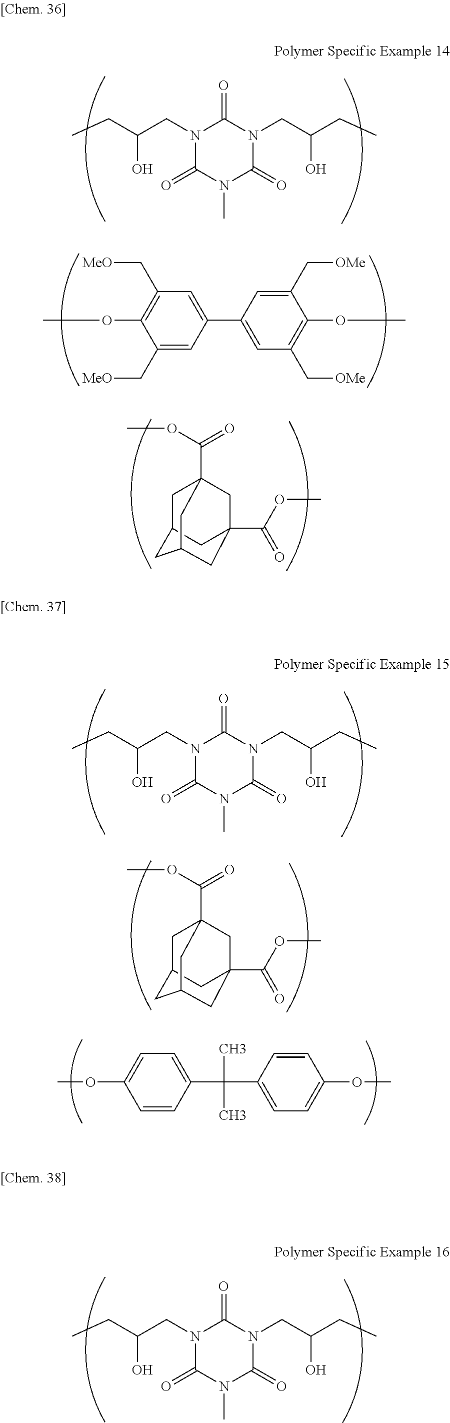

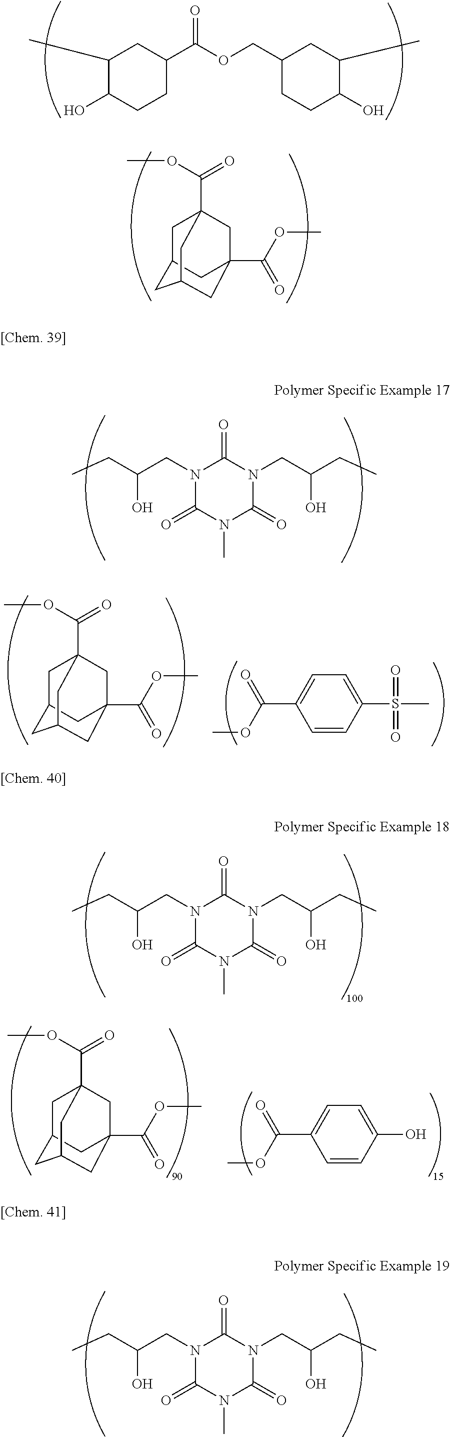

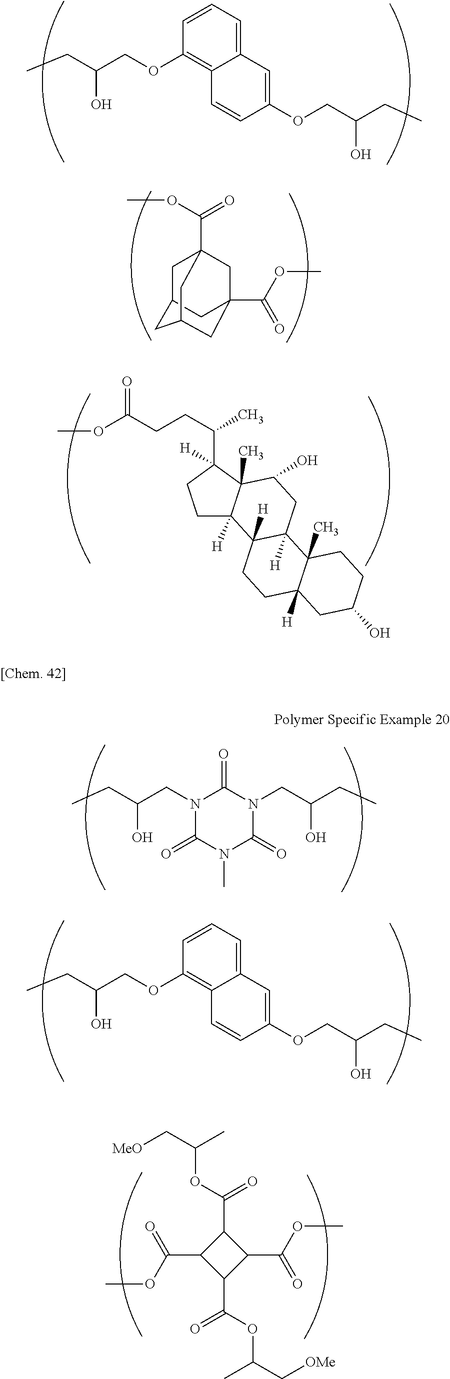

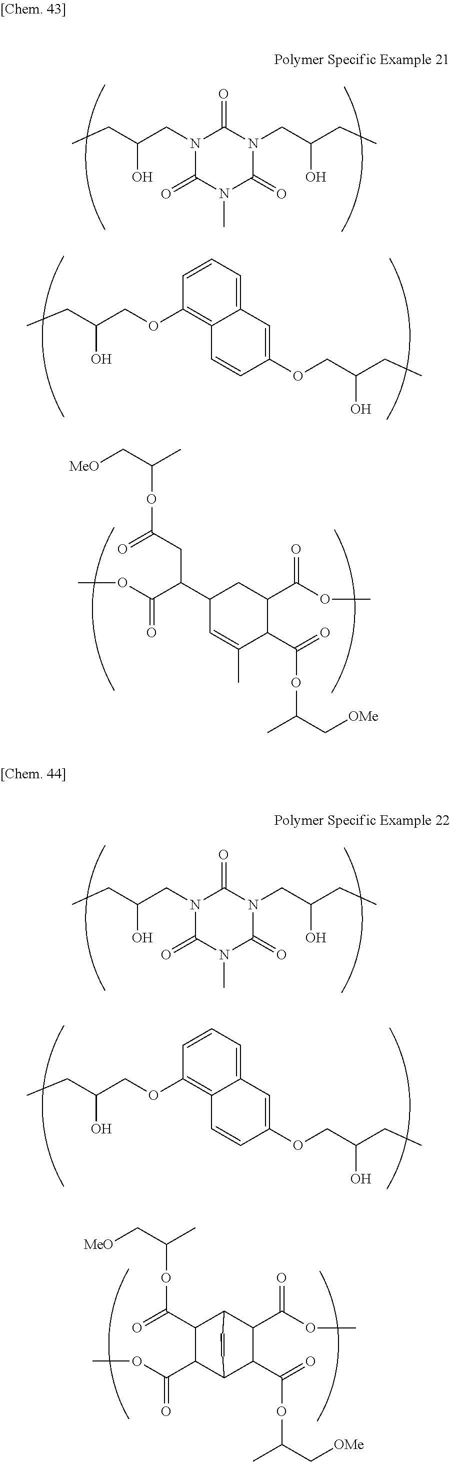

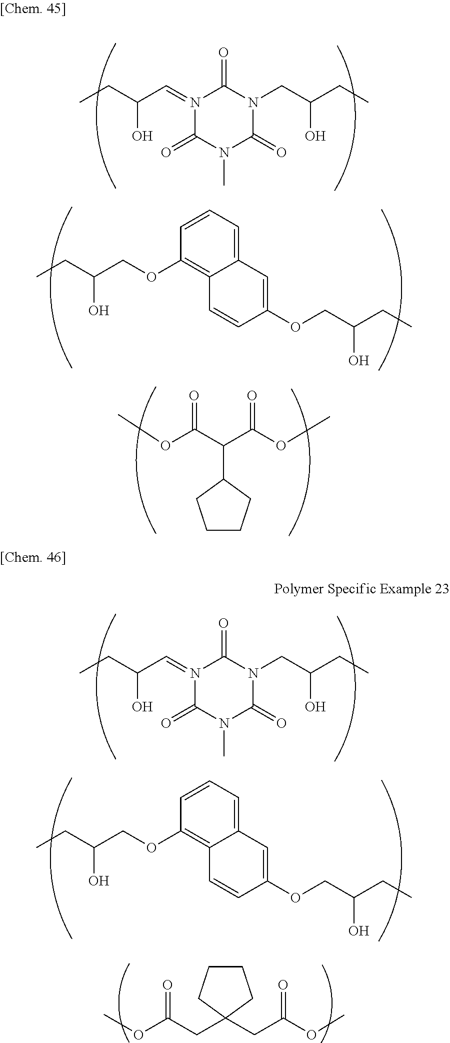

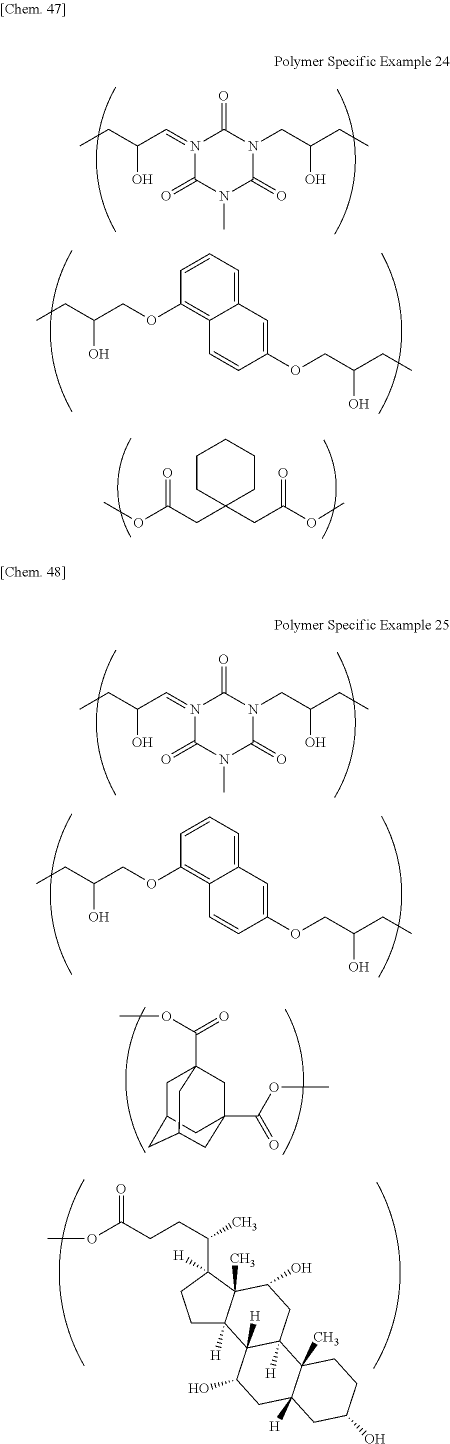

In the above formulas, Me represents a methyl group.

The molecular weight of the polymer is not particularly limited.

The weight average molecular weight of the polymer is, for example, 1,000 to 100,000, preferably 2,000 to 50,000, more preferably 4,000 to 30,000, and particularly preferably 5,00 to 20,000.

The method of manufacturing the polymer is not particularly limited.

An example of the polymer is obtained, for example, by Reaction (I) described below.

(I): A reaction between a compound represented by Formula (1A) described below, a compound represented by Formula (2A) described below, and a compound represented by Formula (3A) described below.

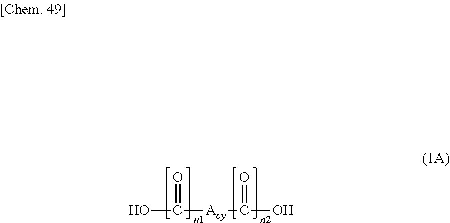

(In Formula (1A), A_{cy}, n1, and n2 have the same meanings as A_{cy}, n1, and n2 in Formula (1), respectively.)

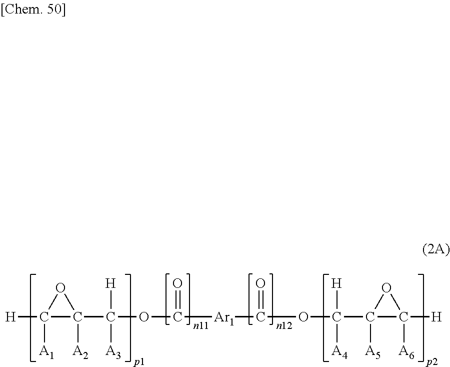

(In Formula (2A), Ar₁, A₁, A₂, A₃, A₄, A₅, A₆, n11, n12, p1, and p2 have the same meaning as Ar₁, A₁, A₂, A₃, A₄, A₅, A₆, n11, n12, p1, and p2 in Formula (2), respectively.)

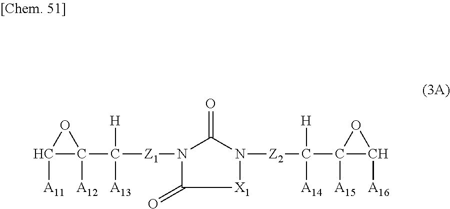

(In Formula (3A), X₁, Z₁, Z₂, A₁₁, A₁₂, A₁₃, A₁₄, A₁₅, and A₁₆ have the same meanings as X₁, Z₁, Z₂, A₁₁, A₁₂, A₁₃, A₁₄, A₁₁, and A₁₆ in Formula (3), respectively.)

In Reaction (I), the mass ratio of the compound represented by Formula (1A) is not particularly limited, and is preferably 30 mass % to 70 mass %, more preferably 35 mass % to 65 mass %, and particularly preferably 40 mass % to 60 mass %, with respect to the total mass of the compound represented by Formula (1A), the compound represented by Formula (2A), and the compound represented by Formula (3A).

In Reaction (I), the mass ratio of the compound represented by Formula (2A) is not particularly limited, and is preferably 5 mass % to 45 mass %, more preferably 10 mass % to 40 mass %, and particularly preferably 15 mass % to 35 mass %, with respect to the total mass of the compound represented by Formula (1A), the compound represented by Formula (2A), and the compound represented by Formula (3A).

In Reaction (I), the mass ratio of the compound represented by Formula (3A) is not particularly limited, and is preferably 5 mass % to 45 mass %, more preferably 10 mass % to 40 mass %, and particularly preferably 15 mass % to 35 mass %, with respect to the total mass of the compound represented by Formula (1A), the compound represented by Formula (2A), and the compound represented by Formula (3A).

Reaction (I) may be carried out, for example, in the presence of a catalyst. The catalyst is, for example, a quaternary phosphonium salt such as tetrabutylphosphonium bromide or ethyltriphenylphosphonium bromide, or a quaternary ammonium salt such as benzyltriethylammonium chloride. As the amount of the catalyst used, an appropriate amount can be selected from the range of 0.1 to 10 mass % with respect to the total mass of the polymer raw material used in the reaction, and the catalyst can be used in the amount. As the temperature and the time for the polymerization reaction, for example, optimum conditions can be selected from the ranges of 80 to 160° C. and 2 to 50 hours.

The content of the polymer in the resist underlayer film-forming composition is not particularly limited, and is preferably 30 mass % to 95 mass %, more preferably 50 mass % to 90 mass %, and particularly preferably 60 mass % to 85 mass % with respect to the amount of the film constituent. The film constituent is a component obtained by removing a volatile component (solvent) from the resist underlayer film-forming composition.

### <Crosslinking Agent>

The resist underlayer film-forming composition preferably includes a crosslinking agent.

The crosslinking agent included as an optional component in the resist underlayer film-forming composition has, for example, a functional group that singly reacts.

Examples of the crosslinking agent include hexamethoxymethylmelamine, tetramethoxymethylbenzoguanamine, 1,3,4,6-tetrakis(methoxymethyl)glycoluril (tetramethoxymethyl glycoluril) (POWDERLINK [registered trademark]1174), 1,3,4,6-tetrakis(butoxymethyl)glycoluril, 1,3,4,6-tetrakis(hydroxymethyl)glycoluril, 1,3-bis(hydroxymethyl)urea, 1,1,3,3-tetrakis(butoxymethyl)urea, and 1,1,3,3-tetrakis(methoxymethyl)urea.

The crosslinking agent may be a nitrogen-containing compound described in WO 2017/187969 A and having 2 to 6 substituents represented by Formula (1d) described below that bond to a nitrogen atom in one molecule.

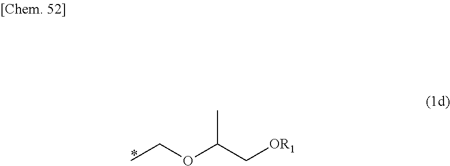

(In Formula (1d), R₁ represents a methyl group or an ethyl group. * represents a bond to a nitrogen atom.)

The nitrogen-containing compound having 2 to 6 substituents represented by Formula (1d) in one molecule may be a glycoluril derivative represented by Formula (1E) described below.

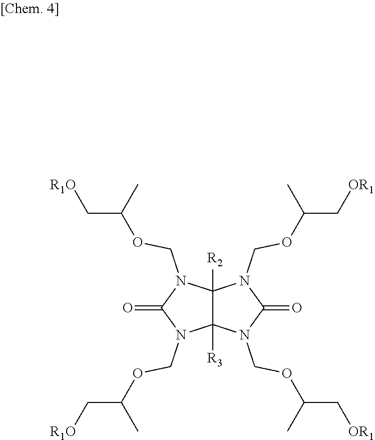

(In Formula (1E), four R₁s each independently represent a methyl group or an ethyl group, and R₂ and R₃ each independently represent a hydrogen atom, an alkyl group having 1 to 4 carbon atoms, or a phenyl group.)

Examples of the glycoluril derivative represented by Formula (1E) include compounds represented by Formulas (1E-1) to (1E-6) described below.

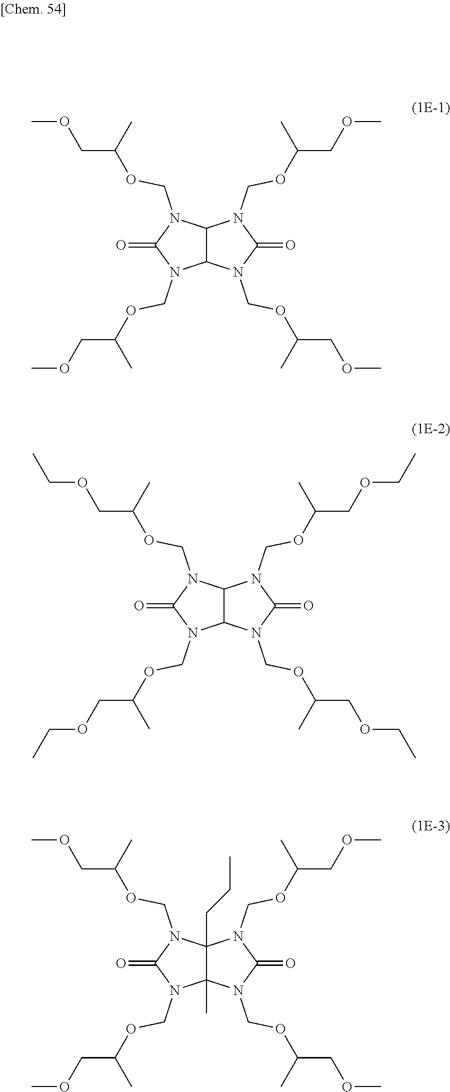

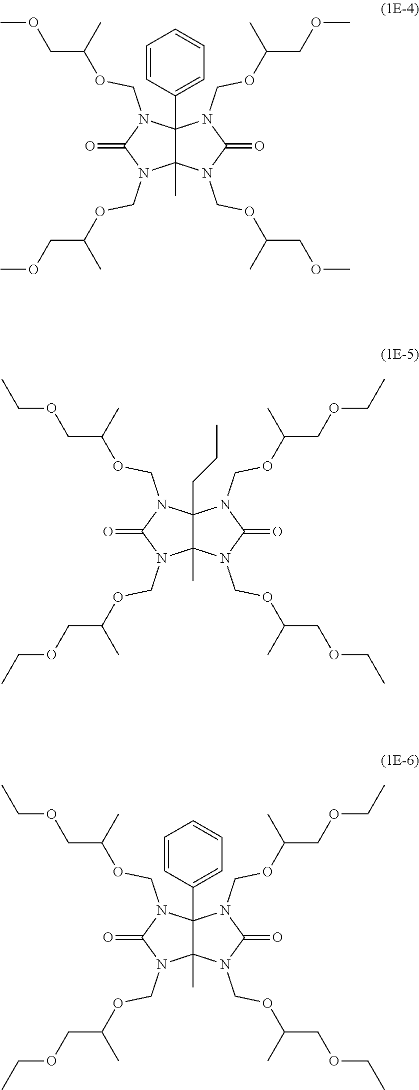

The nitrogen-containing compound having 2 to 6 substituents represented by Formula (1d) in one molecule is obtained by reacting a nitrogen-containing compound having 2 to 6 substituents represented by Formula (2d) described below that bond to a nitrogen atom in one molecule with at least one compound represented by Formula (3d) described below.

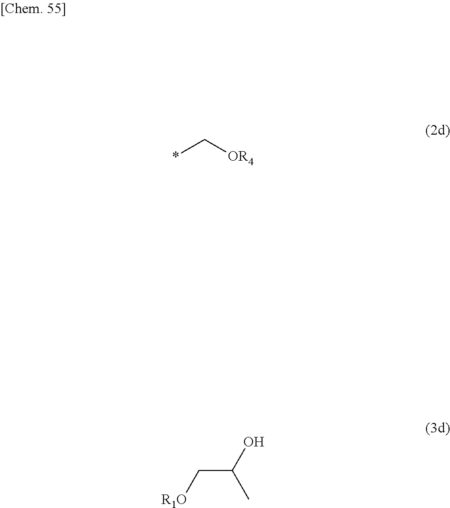

(In Formulas (2d) and (3d), R₁ represents a methyl group or an ethyl group, and R₄ represents an alkyl group having 1 to 4 carbon atoms. * represents a bond to a nitrogen atom.)

The glycoluril derivative represented by Formula (1E) is obtained by reacting a glycoluril derivative represented by Formula (2E) described below with at least one compound represented by Formula (3d).

The nitrogen-containing compound having 2 to 6 substituents represented by Formula (2d) in one molecule is, for example, a glycoluril derivative represented by Formula (2E) described below.

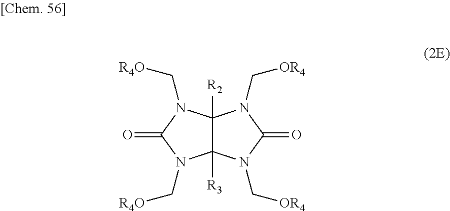

(In Formula (2E), R₂ and R₃ each independently represent a hydrogen atom, an alkyl group having 1 to 4 carbon atoms, or a phenyl group, and R₄s each independently represent an alkyl group having 1 to 4 carbon atoms.)

Examples of the glycoluril derivative represented by Formula (2E) include compounds represented by Formulas (2E-1) to (2E-4) described below. Examples of the compound represented by Formula (3d) include compounds represented by Formulas (3d-1) and (3d-2) described below.

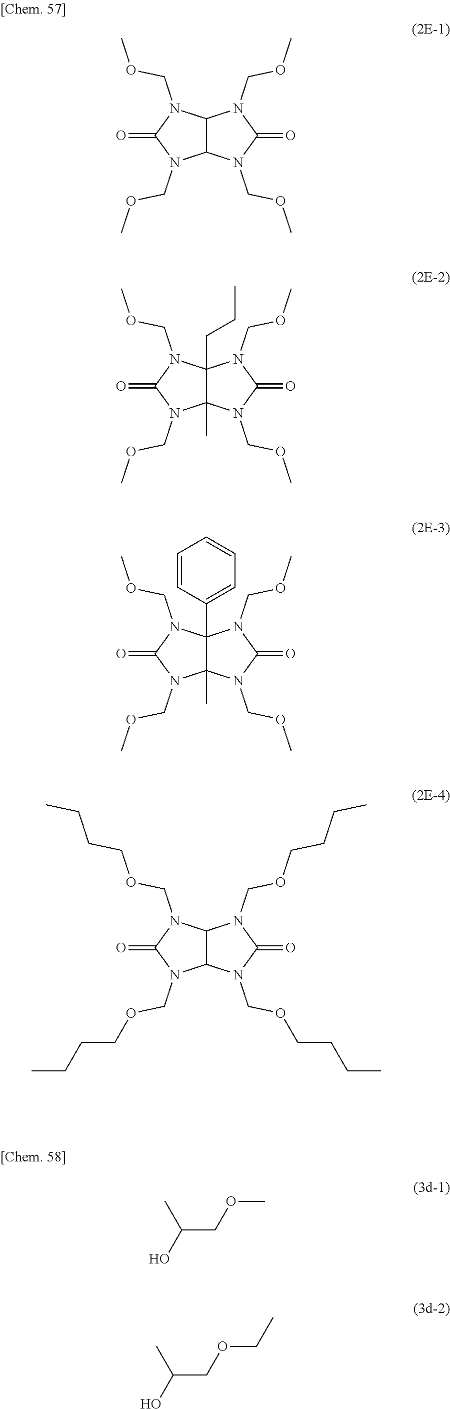

For the content related to the nitrogen-containing compound having 2 to 6 substituents represented by Formula (1d) that bond to a nitrogen atom in one molecule, the entire disclosure of WO 2017/187969 is incorporated in the present application by reference.

The crosslinking agent may be a crosslinkable compound represented by Formula (G-1) or (G-2) described below and described in WO 2014/208542 A.

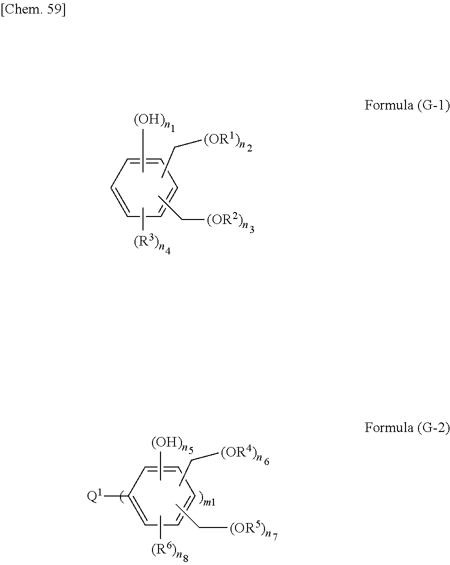

(In the formula, Q¹ represents a single bond or an m1-valent organic group, R¹ and R⁴ each represent an alkyl group having 2 to 10 carbon atoms or an alkyl group having 2 to 10 carbon atoms and having an alkoxy group having 1 to 10 carbon atoms, R² and R⁵ each represent a hydrogen atom or a methyl group, and R³ and R⁶ each represent an alkyl group having 1 to 10 carbon atoms or an aryl group having 6 to 40 carbon atoms.

n1 represents an integer that satisfies 1≤n1≤3, n2 represents an integer that satisfies 2≤n2≤5, n3 represents an integer that satisfies 0≤n3≤3, n4 represents an integer that satisfies 0≤n4≤3, and n1, n2, n3, and n4 satisfy 3 (n1+n2+n3+n4) 6.

n5 represents an integer that satisfies 1≤n5≤3, n6 represents an integer that satisfies 1≤n6≤4, n7 represents an integer that satisfies 0≤n7≤3, n8 represents an integer that satisfies 0≤n8≤3, and n5, n6, n7, and n8 satisfy 2≤(n5+n6+n7+n8)≤5.

m1 represents an integer of 2 to 10.)

The crosslinkable compound represented by Formula (G-1) or (G-2) may be obtained by a reaction of a compound represented by Formula (G-3) or (G-4) described below with a hydroxyl group-containing ether compound or an alcohol having 2 to 10 carbon atoms.

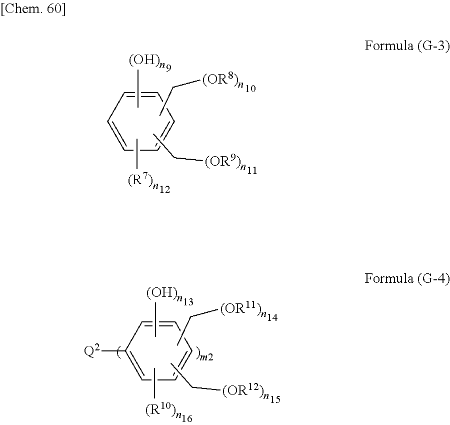

(In the formula, Q² represents a single bond or an m2-valent organic group. R⁰, R⁹, R¹¹, and R¹ each represent a hydrogen atom or a methyl group, and R⁷ and R¹⁰ each represent an alkyl group having 1 to 10 carbon atoms or an aryl group having 6 to 40 carbon atoms.

n9 represents an integer that satisfies 1≤n9≤3, n10 represents an integer that satisfies 2≤n10≤5, n11 represents an integer that satisfies 0≤n11≤3, n12 represents an integer that satisfies 0≤n12≤3, and n9, n10, n11, and n12 satisfy 3 (n9+n10+n11+n12) 6. n13 represents an integer that satisfies 1≤n13≤3, n14 represents an integer that satisfies 1≤n14≤4, n15 represents an integer that satisfies 0≤n15≤3, n16 represents an integer that satisfies 0≤n16≤3, and n13, n14, n15, and n16 satisfy 2 (n13+n14+n15+n16) 5. m2 represents an integer of 2 to 10.)

The compounds represented by Formulas (G-1) and (G-2) can be exemplified below.

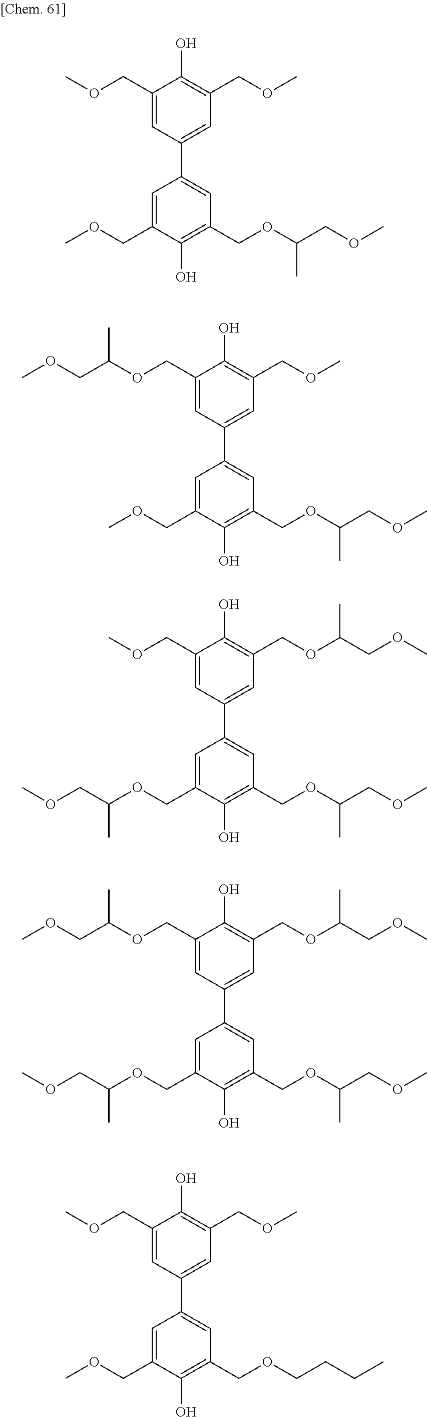

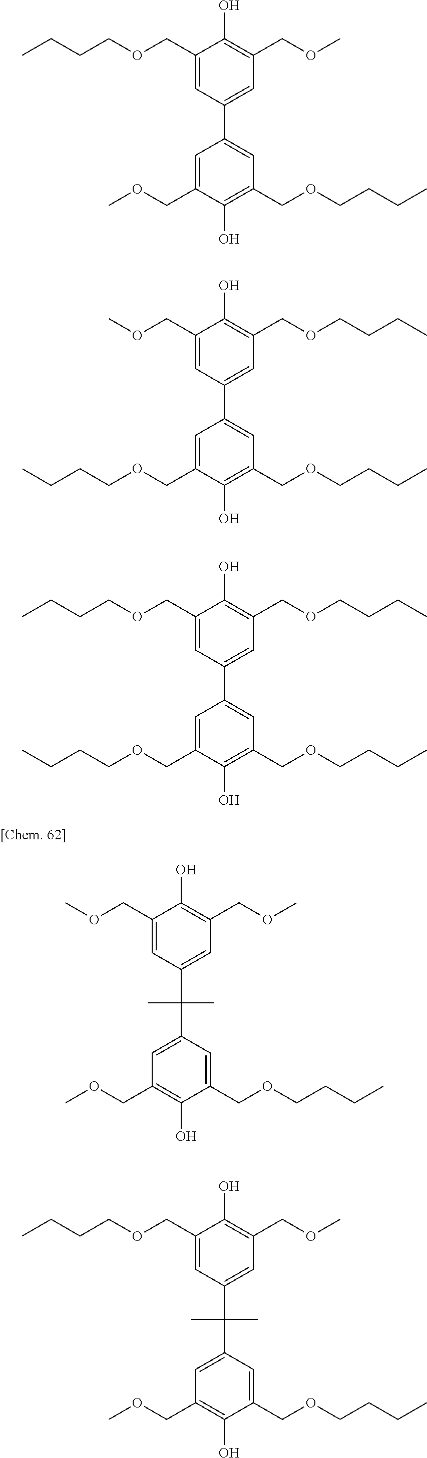

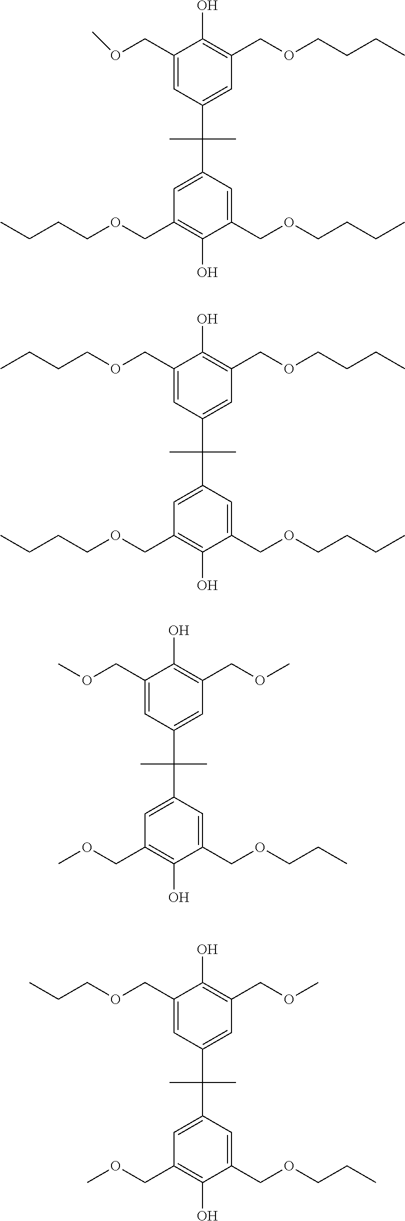

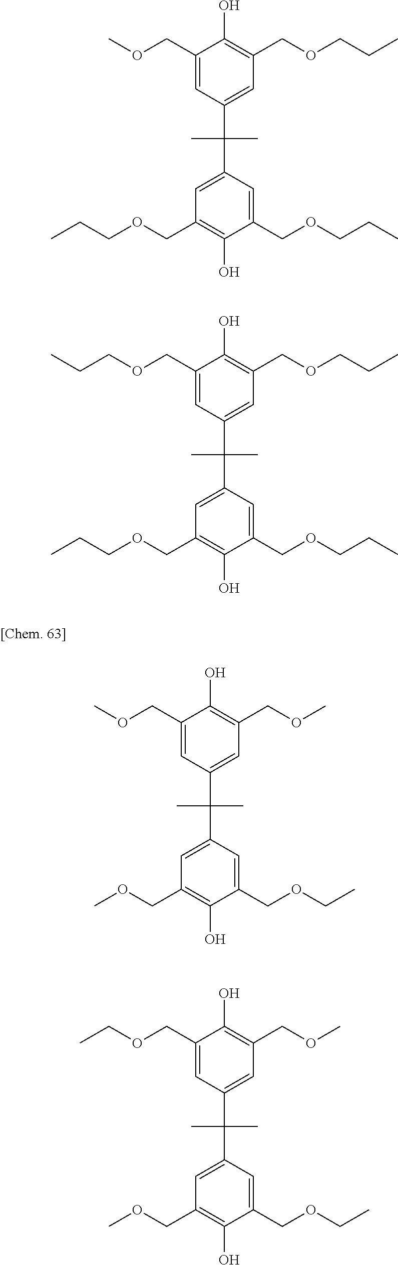

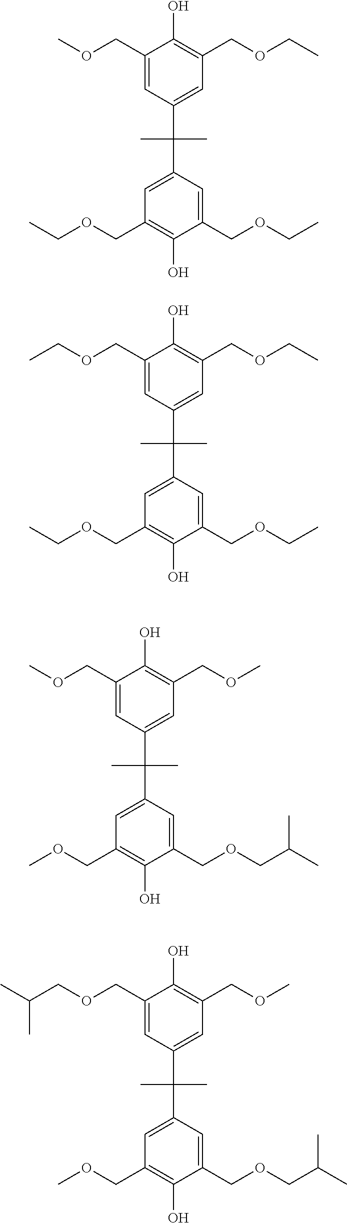

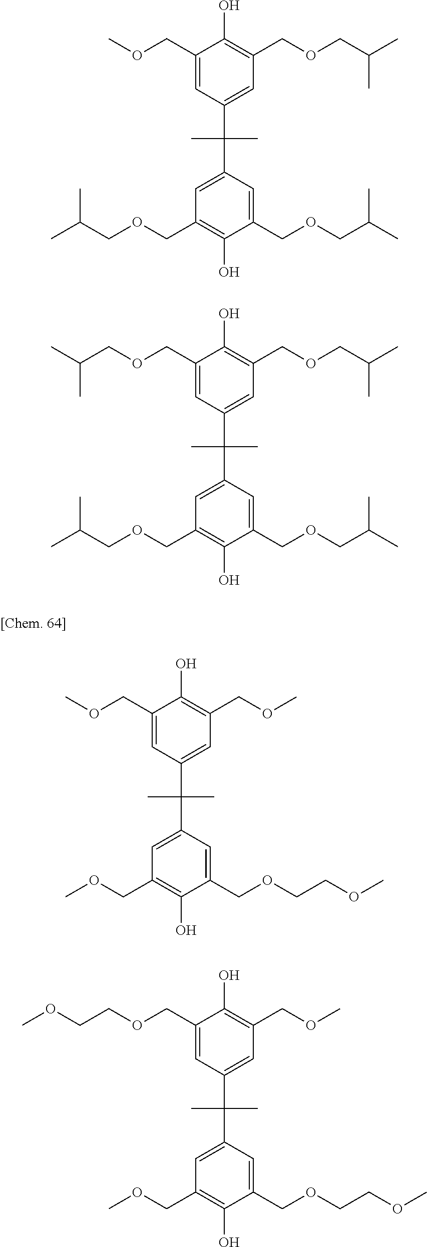

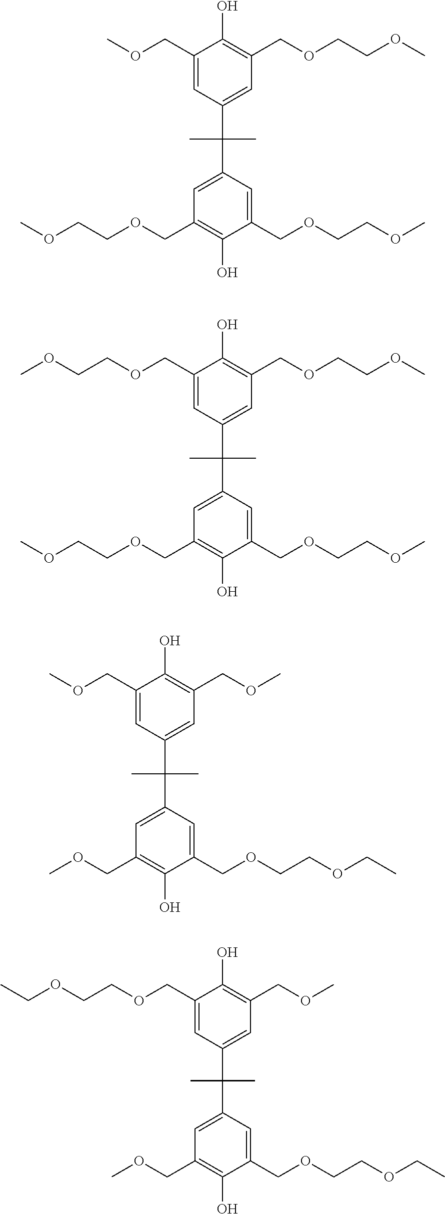

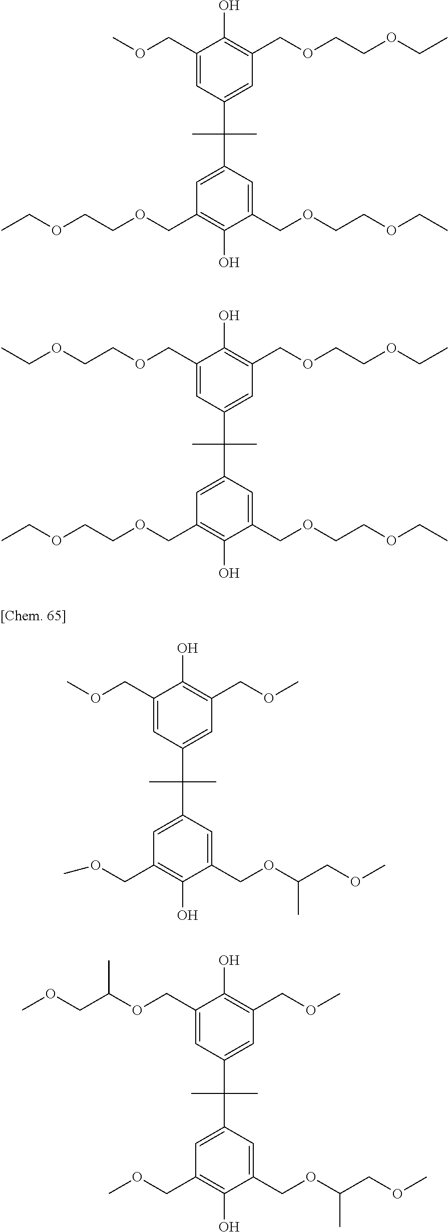

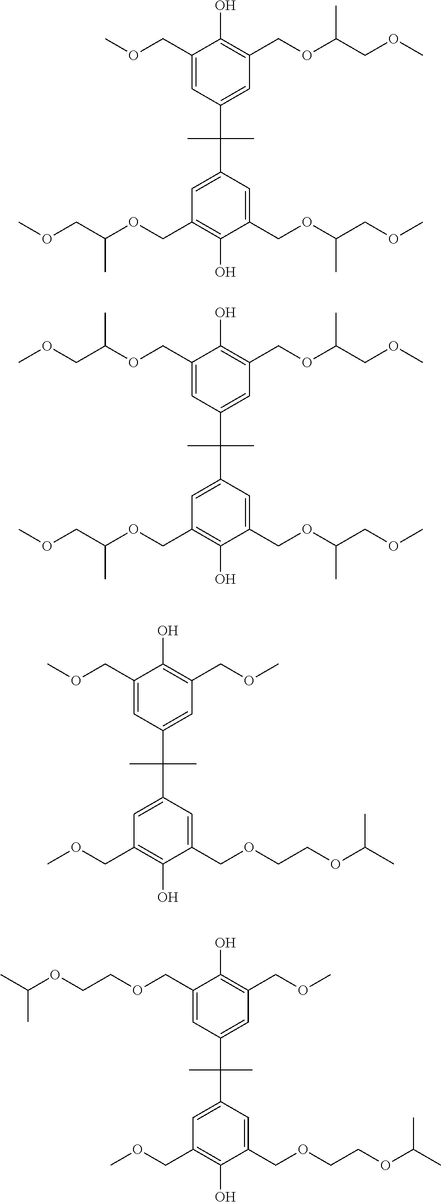

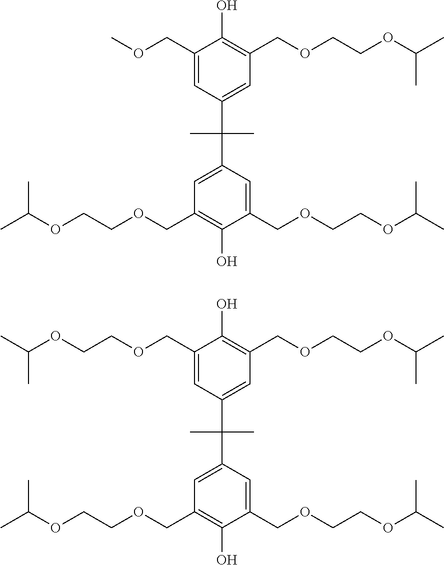

The compounds represented by Formulas (G-3) and (G-4) can be exemplified below.

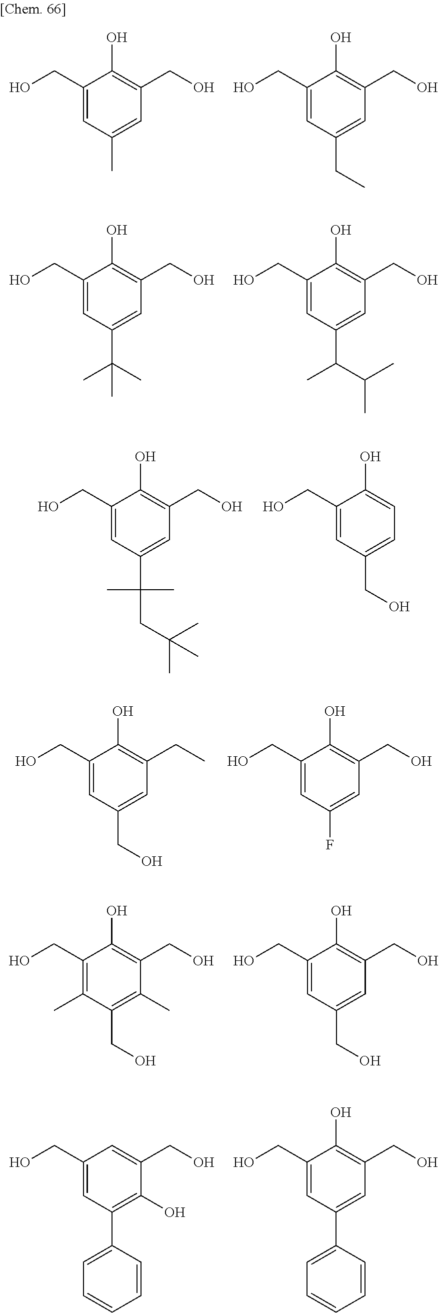

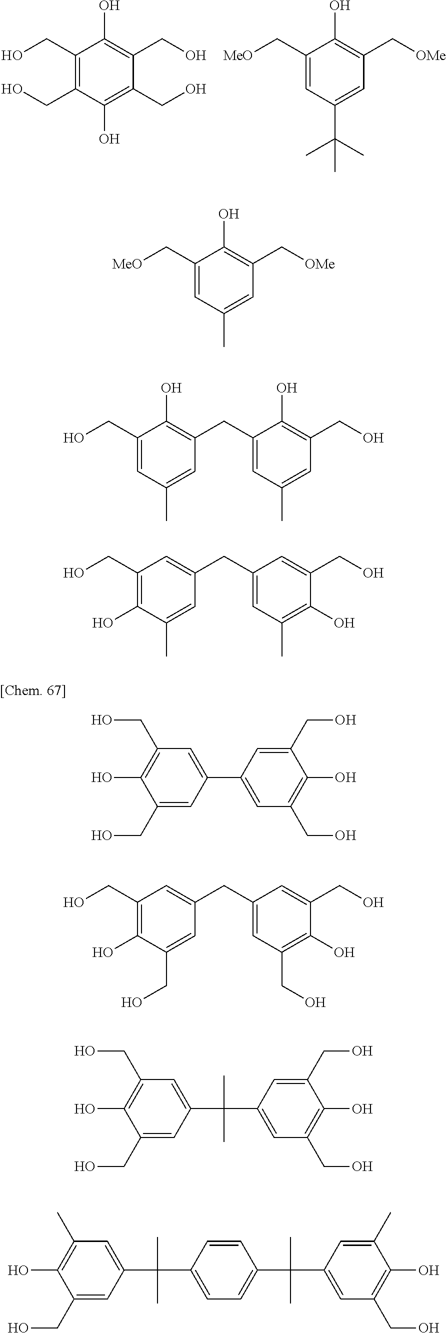

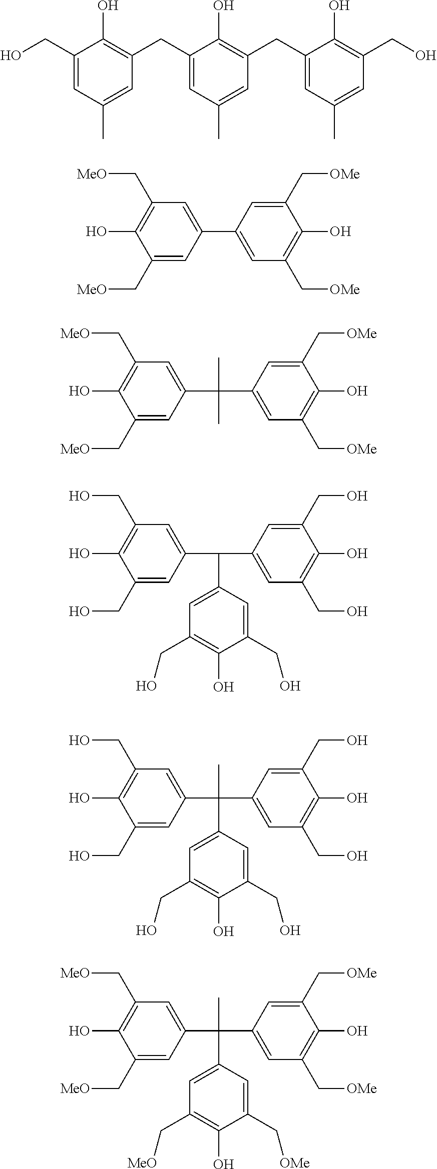

In the formulas, Me represents a methyl group.

The entire disclosure of WO 2014/208542 is incorporated in the present application by reference.

In the case of using the crosslinking agent, the content ratio of the crosslinking agent in the resist underlayer film-forming composition is, for example, 1 mass % to 50 mass %, and preferably 5 mass % to 40 mass % with respect to the polymer.

### <Curing Catalyst>

As the curing catalyst included as an optional component in the resist underlayer film-forming composition, both a thermal acid generator and a photoacid generator can be used, and a thermal acid generator is preferably used.

Examples of the thermal acid generator include sulfonic acid compounds and carboxylic acid compounds such as p-toluenesulfonic acid, trifluoromethanesulfonic acid, pyridinium-p-toluenesulfonate (pyridinium-p-toluenesulfonic acid), pyridinium phenol sulfonic acid, pyridinium-p-hydroxybenzenesulfonic acid (pyridinium p-phenolsulfonic acid salt), pyridinium-trifluoromethanesulfonic acid, salicylic acid, camphorsulfonic acid, 5-sulfosalicylic acid, 4-chlorobenzenesulfonic acid, 4-hydroxybenzenesulfonic acid, benzenedisulfonic acid, 1-naphthalenesulfonic acid, citric acid, benzoic acid, and hydroxybenzoic acid.

Examples of the photoacid generator include onium salt compounds, sulfonimide compounds, and disulfonyldiazomethane compounds.

Examples of the onium salt compounds include iodonium salt compounds such as diphenyliodonium hexafluorophosphate, diphenyliodonium trifluoromethanesulfonate, diphenyliodonium nonafluoronormalbutanesulfonate, diphenyliodonium perfluoronormaloctanesulfonate, diphenyliodonium camphorsulfonate, bis(4-tert-butylphenyl)iodonium camphorsulfonate, and bis(4-tert-butylphenyl)iodonium trifluoromethanesulfonate, and sulfonium salt compounds such as triphenylsulfonium hexafluoroantimonate, triphenylsulfonium nonafluoronormalbutanesulfonate, triphenylsulfonium camphorsulfonate, and triphenylsulfonium trifluoromethanesulfonate.

Examples of the sulfonimide compounds include N-(trifluoromethanesulfonyloxy) succinimide, N-(nonafluoronormalbutanesulfonyloxy) succinimide, N-(camphorsulfonyloxy) succinimide, and N-(trifluoromethanesulfonyloxy) naphthalimide.

Examples of the disulfonyldiazomethane compounds include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyl diazomethane.

Only one kind of curing catalyst can be used, or two or more kinds thereof can be used in combination.

In the case of using the curing catalyst, the content ratio of the curing catalyst is, for example, 0.1 mass % to 50 mass %, and preferably 1 mass % to 30 mass % with respect to the crosslinking agent.

### <Solvent>

As the solvent, an organic solvent is preferable that is generally used in a chemical liquid for a semiconductor lithography process. Specific examples of the solvent include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2-pentanol, methyl 2-hydroxyisobutyrate, ethyl 2-hydroxyisobutyrate, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanone, methoxy cyclopentane, anisole, γ-butyrolactone, N-methylpyrrolidone, N,N-dimethylformamide, and N,N-dimethylacetamide. These solvents can be used singly or in combination of two or more kinds thereof.

Among these solvents, propylene glycol monomethyl ether, propylene glycol monomethyl ether acetate, ethyl lactate, butyl lactate, and cyclohexanone are preferable. Propylene glycol monomethyl ether and propylene glycol monomethyl ether acetate are particularly preferable.

### <Another Component>

To the resist underlayer film-forming composition, a surfactant can be further added in order to further improve the coating property against surface unevenness without generating a pinhole, a striation, and the like.

Examples of the surfactant include polyoxyethylene alkyl ethers such as polyoxyethylene lauryl ether, polyoxyethylene stearyl ether, polyoxyethylene cetyl ether, and polyoxyethylene oleyl ether, polyoxyethylene alkyl allyl ethers such as polyoxyethylene octylphenol ether and polyoxyethylene nonylphenol ether, polyoxyethylene/polyoxypropylene block copolymers, sorbitan fatty acid esters such as sorbitan monolaurate, sorbitan monopalmitate, sorbitan monostearate, sorbitan monooleate, sorbitan trioleate, and sorbitan tristearate, nonion-based surfactants of polyoxyethylene sorbitan fatty acid esters and the like such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate, fluorine-based surfactants such as EFTOP EF301, EF303, and EF352 (manufactured by TOHKEM PRODUCTS Corporation, trade names), MEGAFACE F171, F173, and R-30 (manufactured by DIC Corporation, trade names), Fluorad FC430 and FC431 (manufactured by Sumitomo 3M Limited, trade names), AsahiGuard AG710 and Surflon S-382, SC101, SC102, SC103, SC104, SC105, and SC106 (manufactured by Asahi Glass Co., Ltd., trade names), and organosiloxane polymer KP341 (manufactured by Shin-Etsu Chemical Co., Ltd.).

The amount of the surfactant blended is not particularly limited, and is usually 2.0 mass % or less, and preferably 1.0 mass % or less with respect to the total solid content of the resist underlayer film-forming composition.

These surfactants may be added singly, or may be added in combination of two or more thereof.

The amount of the film constituent included in the resist underlayer film-forming composition, that is, the component excluding the solvent is, for example, 0.01 mass % to 10 mass % of the resist underlayer film-forming composition.

The resist underlayer film-forming composition of the present invention is manufactured, for example, with a method in which a polymer, a solvent, and the like are mixed with a known method. For being used as a resist underlayer film-forming composition, the composition is required to be in a uniform solution state. The manufactured composition is preferably manufactured by filtration with a filter or the like in order to remove a metal impurity, a foreign matter, and the like present in the composition.

One of the measures in evaluating whether the resist underlayer film-forming composition is in a uniform solution state is observation of the passability through a specific microfilter, and the resist underlayer film-forming composition according to the present invention preferably passes through microfilters having pore sizes of 0.1 μm, 0.05 μm, 0.03 μm, 0.02 μm, and 0.01 μm and exhibits a uniform solution state.

The resist underlayer film-forming composition is, for example, a resist underlayer film-forming composition for formation of an underlayer of a negative photoresist or a positive photoresist, and is preferably a resist underlayer film-forming composition for formation of an underlayer of a negative photoresist.

The resist underlayer film-forming composition is, for example, a resist underlayer film-forming composition for photolithography using an i-line (365 nm), a KrF excimer laser (248 nm), an ArF excimer laser (193 nm), extreme ultraviolet (EUV: 13.5 nm), or an electron beam (EB), and is preferably a resist underlayer film-forming composition for photolithography using an ArF excimer laser or EUV.

### (Resist Underlayer Film)

The resist underlayer film of the present invention is a cured product of the above-described resist underlayer film-forming composition.

The resist underlayer film can be manufactured, for example, by applying the above-described resist underlayer film-forming composition onto a semiconductor substrate and baking the composition.

Examples of the semiconductor substrate onto which the resist underlayer film-forming composition is applied include silicon wafers, germanium wafers, and compound semiconductor wafers of gallium arsenide, indium phosphide, gallium nitride, indium nitride, aluminum nitride, and the like.

In the case of using a semiconductor substrate having a surface on which an inorganic film is formed, the inorganic film is formed with, for example, an atomic layer deposition (ALD) method, a chemical vapor deposition (CVD) method, a reactive sputtering method, an ion plating method, a vacuum deposition method, or a spin coating method (spin-on-glass: SOG). Examples of the inorganic film include a polysilicon film, a silicon oxide film, a silicon nitride film, a boro-phospho silicate glass (BPSG) film, a titanium nitride film, a titanium nitride oxide film, a tungsten film, a gallium nitride film, and a gallium arsenide film. The inorganic film may be a single layer or a multilayer including two or more layers. In the case of a multilayer, layers in the multilayer may be the same kind of inorganic films or different kinds of inorganic films.

The thickness of the inorganic film is not particularly limited.

The resist underlayer film-forming composition of the present invention is applied onto such a semiconductor substrate with an appropriate application method using a spinner, a coater, or the like. Then, the composition is baked using a heating unit such as a hot plate to form a resist underlayer film. The baking conditions are appropriately selected from a baking temperature of 100° C. to 400° C. and a baking time of 0.3 minutes to 60 minutes. It is preferable that the baking temperature be 120° C. to 350° C. and the baking time be 0.5 minutes to 30 minutes, and it is more preferable that the baking temperature be 150° C. to 300° C. and the baking time be 0.8 minutes to 10 minutes.

The film thickness of the resist underlayer film is, for example, 0.001 μm (1 nm) to 10 μm, 0.002 μm (2 nm) to 1 μm, 0.005 μm (5 nm) to 0.5 μm (500 nm), 0.001 μm (1 nm) to 0.05 μm (50 nm), 0.002 μm (2 nm) to 0.05 μm (50 nm), 0.003 μm (3 nm) to 0.05 μm (50 nm), 0.004 μm (4 nm) to 0.05 μm (50 nm), 0.005 μm (5 nm) to 0.05 μm (50 nm), 0.003 μm (3 nm) to 0.03 μm (30 nm), 0.003 μm (3 nm) to 0.02 μm (20 nm), 0.005 μm (5 nm) to 0.02 μm (20 nm), 0.005 μm (5 nm) to 0.02 μm (20 nm), 0.003 μm (3 nm) to 0.01 μm (10 nm), 0.005 μm (5 nm) to 0.01 μm (10 nm), 0.003 μm (3 nm) to 0.006 μm (6 nm), or 0.005 μm (5 nm).

### (Semiconductor Processing Substrate)

The semiconductor processing substrate of the present invention includes a semiconductor substrate and the resist underlayer film of the present invention.

Examples of the semiconductor substrate include the above-described semiconductor substrates.

The resist underlayer film is disposed, for example, on the semiconductor substrate.

### (Method of Manufacturing Semiconductor Element and Method of Forming Pattern)

The method of manufacturing a semiconductor element of the present invention includes at least the following steps:
a step of forming a resist underlayer film on a semiconductor substrate using the resist underlayer film-forming composition of the present invention, and
a step of forming a resist film on the resist underlayer film.

The method of forming a pattern of the present invention includes at least the following steps: a step of forming a resist underlayer film on a semiconductor substrate using the resist underlayer film-forming composition of the present invention;
a step of forming a resist film on the resist underlayer film;
a step of irradiating the resist film with light or an electron beam and then developing the resist film to obtain a resist pattern; and
a step of etching the resist underlayer film using the resist pattern as a mask.

The resist film is usually formed on the resist underlayer film.

The film thickness of the resist film is preferably 200 nm or less, more preferably 150 nm or less, still more preferably 100 nm or less, and particularly preferably 80 nm or less. The film thickness of the resist film is preferably 10 nm or more, more preferably 20 nm or more, and particularly preferably 30 nm or more.

The resist film formed on the resist underlayer film with a known method (such as application and baking of a resist) is not particularly limited as long as it responds to light or an electron beam (EB) used for irradiation. Both a negative photoresist and a positive photoresist can be used, and use of a negative photoresist is preferable.

The light or the electron beam is not particularly limited. Examples thereof include an i-line (365 nm), a KrF excimer laser (248 nm), an ArF excimer laser (193 nm), extreme ultraviolet (EUV: 13.5 nm), and an electron beam (EB), and an ArF excimer laser (193 nm) and extreme ultraviolet (EUV: 13.5 nm) are preferable.

In the present description, a resist that responds to an EB is also referred to as a photoresist.

Examples of the photoresist include a positive photoresist including a novolac resin and 1,2-naphthoquinone diazide sulfonic acid ester, a chemically amplified photoresist including a binder having a group that is decomposed by an acid to increase the alkali dissolution rate and a photoacid generator, a chemically amplified photoresist including a low-molecular compound that is decomposed by an acid to increase the alkali dissolution rate of a photoresist, an alkali-soluble binder, and a photoacid generator, a chemically amplified photoresist including a binder having a group that is decomposed by an acid to increase the alkali dissolution rate, a low-molecular compound that is decomposed by an acid to increase the alkali dissolution rate of a photoresist, and a photoacid generator, and a resist containing a metal element. Examples thereof include V146G (trade name) manufactured by JSR Corporation, APEX-E (trade name) manufactured by Shipley, PAR710 (trade name) manufactured by SUMITOMO CHEMICAL COMPANY, LIMITED, and AR2772 and SEPR430 (trade names) manufactured by Shin-Etsu Chemical Co., Ltd. Furthermore, examples thereof include fluorine atom-containing polymer-based photoresists as described in Proc. SPIE, Vol. 3999, 330-334 (2000), Proc. SPIE, Vol. 3999, 357-364 (2000), and Proc. SPIE, Vol. 3999, 365-374 (2000).

Furthermore, so-called resist compositions and metal-containing resist compositions can be used that include resist compositions, radiation-sensitive resin compositions, and high-resolution patterning compositions based on organometallic solutions, described in WO 2019/188595, WO 2019/187881, WO 2019/187803, WO 2019/167737, WO 2019/167725, WO 2019/187445, WO 2019/167419, WO 2019/123842, WO 2019/054282, WO 2019/058945, WO 2019/058890, WO 2019/039290, WO 2019/044259, WO 2019/044231, WO 2019/026549, WO 2018/193954, WO 2019/172054, WO 2019/021975, WO 2018/230334, WO 2018/194123, JP 2018-180525, WO 2018/190088, JP 2018-070596, JP 2018-028090, JP 2016-153409, JP 2016-130240, JP 2016-108325, JP 2016-047920, JP 2016-035570, JP 2016-035567, JP 2016-035565, JP 2019-101417, JP 2019-117373, JP 2019-052294, JP 2019-008280, JP 2019-008279, JP 2019-003176, JP 2019-003175, JP 2018-197853, JP 2019-191298, JP 2019-061217, JP 2018-045152, JP 2018-022039, JP 2016-090441, JP 2015-10878, JP 2012-168279, JP 2012-022261, JP 2012-022258, JP 2011-043749, JP 2010-181857, JP 2010-128369, WO 2018/031896, JP 2019-113855, WO 2017/156388, WO 2017/066319, JP 2018-41099, WO 2016/065120, WO 2015/026482, JP 2016-29498, JP 2011-253185, and the like, but the resist compositions are not limited thereto.

Examples of the resist composition include the following compositions.

An active ray-sensitive or radiation-sensitive resin composition including: a resin A having a repeating unit having an acid-decomposable group in which a polar moiety is protected by a protecting moiety that is desorbed by the action of an acid; and a compound represented by the following general formula (21).

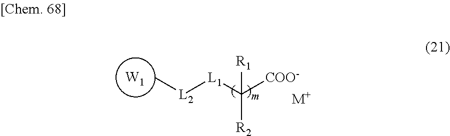

In the general formula (21), m represents an integer of 1 to 6.

R₁ and R₂ each independently represent a fluorine atom or a perfluoroalkyl group.

L₁ represents —O—, —S—, —COO—, —SO₂—, or —SO₃—.

L₂ represents an alkylene group optionally having a substituent, or a single bond.

W₁ represents a cyclic organic group optionally having a substituent.

M⁺ represents a cation.

A metal-containing film-forming composition for extreme ultraviolet or electron beam lithography, including: a compound having a metal-oxygen covalent bond; and a solvent, wherein a metal element included in the compound belongs to the third to seventh periods of Groups 3 to 15 of the periodic table.

A radiation-sensitive resin composition including: a polymer having a first structural unit represented by Formula (31) described below and a second structural unit represented by Formula (32) described below and containing an acid-dissociable group; and an acid generator.

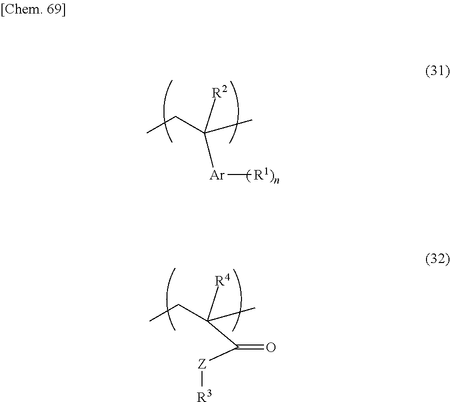

(In Formula (31), Ar represents a group obtained by removing (n+1) hydrogen atoms from an arene having 6 to 20 carbon atoms. R¹ represents a hydroxy group, a sulfanyl group, or a monovalent organic group having 1 to 20 carbon atoms. n is an integer of 0 to 11. In a case where n is 2 or more, a plurality of R s are the same or different. R² represents a hydrogen atom, a fluorine atom, a methyl group, or a trifluoromethyl group. In Formula (32), R³ represents a monovalent group having 1 to 20 carbon atoms and containing the acid-dissociable group. Z represents a single bond, an oxygen atom, or a sulfur atom. R⁴ represents a hydrogen atom, a fluorine atom, a methyl group, or a trifluoromethyl group.)

A resist composition including: a resin (A1) including a structural unit having a cyclic carbonate structure, a structural unit represented by the following formula, and a structural unit having an acid-unstable group; and an acid generator.

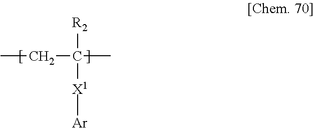

[In the formula,

R² represents an alkyl group having 1 to 6 carbon atoms and optionally having a halogen atom or represents a hydrogen atom or a halogen atom, X¹ represents a single bond, —CO—O—*, or —CO—NR⁴—*, * represents a bond with —Ar, R⁴ represents a hydrogen atom or an alkyl group having 1 to 4 carbon atoms, and Ar represents an aromatic hydrocarbon group having 6 to 20 carbon atoms and optionally having one or more moieties selected from the group consisting of a hydroxy group and a carboxyl group.]

Examples of the resist film include the following.

A resist film including a base resin including a repeating unit represented by Formula (a1) described below and/or a repeating unit represented by Formula (a2) described below, and a repeating unit that generates a polymer main chain-bonded acid by exposure.

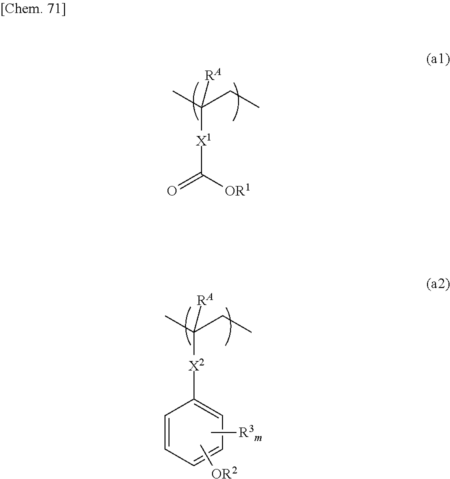

(In Formulas (a1) and (a2), R^{A}s each independently represent a hydrogen atom or a methyl group. R¹ and R₂ each independently represent a tertiary alkyl group having 4 to 6 carbon atoms. R₃ each independently represents a fluorine atom or a methyl group. m is an integer of 0 to 4. X¹ represents a single bond, a phenylene group, a naphthylene group, or a linking group having 1 to 12 carbon atoms and including at least one selected from an ester bond, a lactone ring, a phenylene moiety, and a naphthylene moiety. X2 represents a single bond, an ester bond, or an amide bond.)

Examples of a resist material include the following.

A resist material including a polymer having a repeating unit represented by Formula (b1) or (b2) described below.

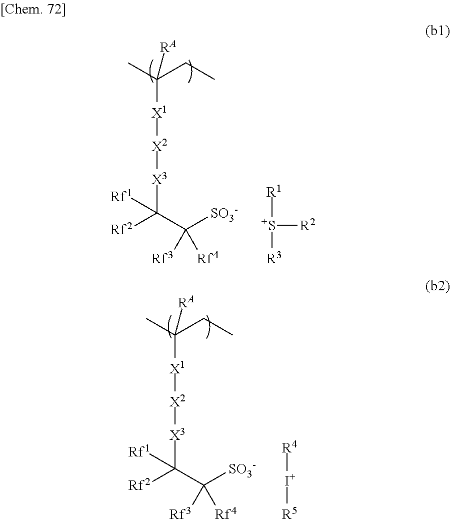

(In Formulas (b1) and (b2), R^{A} represents a hydrogen atom or a methyl group. X¹ represents a single bond or an ester group. X² represents a linear, branched, or cyclic alkylene group having 1 to 12 carbon atoms or arylene group having 6 to 10 carbon atoms, and a part of a methylene moiety included in the alkylene group may be substituted with an ether moiety, an ester moiety, or a lactone ring-containing moiety, and at least one hydrogen atom included in X2 is substituted with a bromine atom. X3 is a single bond, an ether group, an ester group, or a linear, branched, or cyclic alkylene group having 1 to 12 carbon atoms, and a part of a methylene moiety included in the alkylene group may be substituted with an ether moiety or an ester moiety. Rf¹ to Rf⁴ each independently represent a hydrogen atom, a fluorine atom, or a trifluoromethyl group, and at least one of Rf¹ to Rf⁴ represents a fluorine atom or a trifluoromethyl group. Alternatively, Rf¹ and Rf² may be combined to form a carbonyl group. R¹ to R⁵ each independently represent a linear, branched, or cyclic alkyl group having 1 to 12 carbon atoms, a linear, branched, or cyclic alkenyl group having 2 to 12 carbon atoms, an alkynyl group having 2 to 12 carbon atoms, an aryl group having 6 to 20 carbon atoms, an aralkyl group having 7 to 12 carbon atoms, or an aryloxyalkyl group having 7 to 12 carbon atoms, and some or all of hydrogen atoms of these groups may be substituted with a hydroxy moiety, a carboxy moiety, a halogen atom, an oxo moiety, a cyano moiety, an amide moiety, a nitro moiety, a sultone moiety, a sulfone moiety, or a sulfonium salt-containing moiety, and some of methylene moieties included in these groups may be substituted with an ether moiety, an ester moiety, a carbonyl moiety, a carbonate moiety, or a sulfonic acid ester moiety. R¹ and R² may be bonded to form a ring together with a sulfur atom to which R¹ and R² are bonded.)

A resist material containing a base resin containing a polymer including a repeating unit represented by Formula (a) described below.

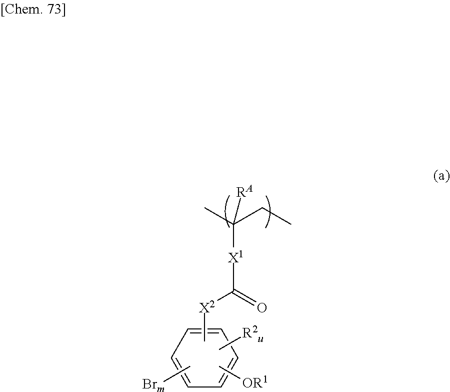

(In Formula (a), R^{A} represents a hydrogen atom or a methyl group. R¹ represents a hydrogen atom or an acid-unstable group. R² represents a linear, branched, or cyclic alkyl group having 1 to 6 carbon atoms or a halogen atom other than bromine. X represents a single bond, a phenylene group, or a linear, branched, or cyclic alkylene group having 1 to 12 carbon atoms and optionally including an ester moiety or a lactone ring. X2 represents —O—, —O—CH₂—, or —NH—. m is an integer of 1 to 4. u is an integer of 0 to 3. Here, m+u is an integer of 1 to 4.)

A resist composition that generates an acid by exposure to change in solubility due to an action of the acid in a developer,
the resist composition including: a base material component (A) that changes in solubility due to an acid of an acid in a developer; and a fluorine additive component (F) that exhibits decomposability in an alkaline developer,
the fluorine additive component (F) including a fluororesin component (F1) having a constituent unit (f1) including a base dissociable group and a constituent unit (f2) including a group represented by the following general formula (f2-r-1).

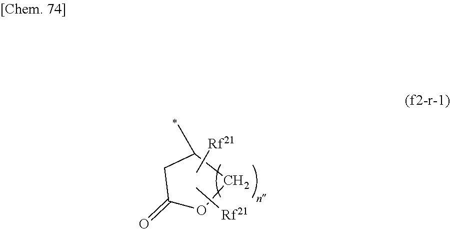

[In the formula (f2-r-1), Rf²¹s each independently represent a hydrogen atom, an alkyl group, an alkoxy group, a hydroxyl group, a hydroxyalkyl group, or a cyano group. n″ is an integer of 0 to 2. * represents s a bond.]

The constituent unit (f1) includes a constituent unit represented by the following general formula (f1-1) or a constituent unit represented by the following general formula (f1-2).

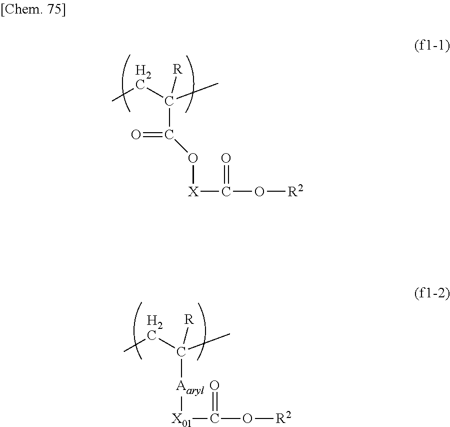

[In the formulas (f1-1) and (f1-2), Rs each independently represent a hydrogen atom, an alkyl group having 1 to 5 carbon atoms, or a halogenated alkyl group having 1 to 5 carbon atoms. X represents a divalent linking group not having an acid-dissociable site. A_{aryl} represents a divalent aromatic cyclic group optionally having a substituent. X₀₁ represents a single bond or a divalent linking group. R²s each independently represent an organic group having a fluorine atom.]

Examples of a coating, a coating solution, and a coating composition include the following.

A coating including a metal oxo-hydroxo network having an organic ligand with a metal-carbon bond and/or a metal-carboxylate bond.

An inorganic oxo/hydroxo-based composition.

A coating solution including: an organic solvent; a first organometallic composition represented by the formula R_{z}SnO_{(2-(z/2)-(x/2))}(OH)ₓ (here, 0<z≤2 and 0<(z+x)≤4), the formula R′ₙSnX₄₋ₙ (here, n=1 or 2), or a mixture thereof, wherein R and R′ independently represent a hydrocarbyl group having 1 to 31 carbon atoms and X represents a ligand having a hydrolysable bond to Sn or a combination of such ligands; and a hydrolysable metal compound represented by the formula MX′_{V} (wherein M represents a metal selected from Groups 2 to 16 of the periodic table, v is a number of v=2 to 6, and X′ represents a ligand having a hydrolysable M-X bond or a combination of such ligands).

A coating solution including an organic solvent and a first organometallic compound represented by the formula RSnO_{(3/2-x/2)}(OH)ₓ (wherein 0<x<3) wherein the solution contains about 0.0025 M to about 1.5 M tin, R represents an alkyl group or a cycloalkyl group having 3 to 31 carbon atoms, and the alkyl group or the cycloalkyl group is bonded to tin at a secondary or tertiary carbon atom.

An inorganic patterning precursor aqueous solution including a mixture of water, a metal suboxide cation, a polyatomic inorganic anion, and a radiation-sensitive ligand including a peroxide group.

Irradiation with light or an electron beam is performed, for example, through a mask (reticle) for formation of a predetermined pattern.

The exposure amount and the irradiation energy of an electron beam are not particularly limited.

Post exposure bake (PEB) may be performed after irradiation with light or an electron beam and before development.

The baking temperature is not particularly limited, and is preferably 60° C. to 150° C., more preferably 70° C. to 120° C., and particularly preferably 75° C. to 110° C.

The baking time is not particularly limited, and is preferably 1 second to 10 minutes, more preferably 10 seconds to 5 minutes, and particularly preferably 30 seconds to 3 minutes.

For the development, for example, an alkaline developer is used.

The developing temperature is, for example, 5° C. to 50° C. The developing time is, for example, 10 seconds to 300 seconds.

As the alkaline developer, for example, an aqueous solution of an alkali can be used, and examples of the alkali include inorganic alkalis such as sodium hydroxide, potassium hydroxide, sodium carbonate, sodium silicate, sodium metasilicate, and ammonia water, primary amines such as ethylamine and n-propylamine, secondary amines such as diethylamine and di-n-butylamine, tertiary amines such as triethylamine and methyldiethylamine, alcoholamines such as dimethylethanolamine and triethanolamine, quaternary ammonium salts such as tetramethylammonium hydroxide, tetraethylammonium hydroxide, and choline, and cyclic amines such as pyrrole and piperidine. Furthermore, an alcohol such as isopropyl alcohol, or a nonion-based surfactant can be added in an appropriate amount to the aqueous solution of an alkali and used. Among these developers, an aqueous solution of a quaternary ammonium salt is preferable, and an aqueous solution of tetramethylammonium hydroxide and an aqueous solution of choline are more preferable. Furthermore, a surfactant or the like can be added to these developers. A method can also be used in which an organic solvent such as butyl acetate is used in place of the alkaline developer for development to develop a portion where the alkali dissolution rate of the photoresist is not improved.

Next, the resist underlayer film is etched using the formed resist pattern as a mask. The etching may be dry etching or wet etching, and dry etching is preferable.

In a case where the inorganic film is formed on a surface of the used semiconductor substrate, a surface of the inorganic film is exposed, and in a case where the inorganic film is not formed on a surface of the used semiconductor substrate, a surface of the semiconductor substrate is exposed. Then, a semiconductor element can be manufactured through a step of processing the semiconductor substrate with a known method (dry etching method or the like).

### EXAMPLES

Next, the contents of the present invention will be specifically described with reference to Examples, but the present invention is not limited thereto.

### <Measurement of Molecular Weight>

Apparatus and the like will be shown that are used for measurement of the weight average molecular weight of polymers obtained in Synthesis Examples and Comparative Synthesis Examples described below.

Apparatus: HLC-8420GPC manufactured by Tosoh Corporation

GPC column: Shodex [registered trademark] Asahipak [registered trademark](manufactured by Showa Denko K.K.) Column temperature: 40° C.

Flow rate: 0.35 mL/min

Eluent: tetrahydrofuran (THF)

Standard sample: polystyrene (manufactured by Tosoh Corporation)

### Synthesis Example 1

Into a reaction flask, 5.00 g of monomethyl diglycidyl isocyanuric acid (manufactured by SHIKOKU CHEMICALS CORPORATION, product name: Me-DGIC, 30 wt % propylene glycol monomethyl ether solution), 1.66 g of 1,6-bis(2,3-epoxypropane-1-yloxy)naphthalene (manufactured by DIC Corporation, trade name: HP-4032D), 2.77 g of 1,3-adamantane dicarboxylic acid, 0.30 g of tetrabutylphosphonium bromide, and 21.41 g of propylene glycol monomethyl ether were added, and the mixture was heated and stirred under a nitrogen atmosphere at an internal temperature of 105° C. for 24 hours. The obtained reaction product corresponded to Formula (1-1), and the weight average molecular weight Mw measured in terms of polystyrene by GPC was 8800.

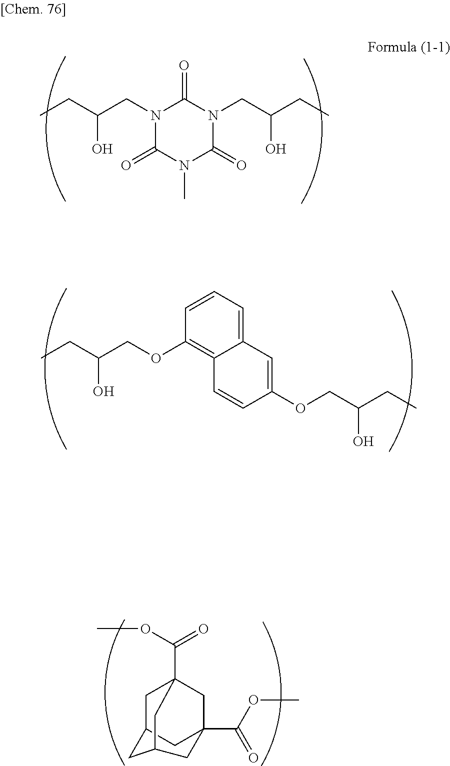

### Synthesis Example 2

Into a reaction flask, 4.00 g of monomethyl diglycidyl isocyanuric acid (manufactured by SHIKOKU CHEMICALS CORPORATION, product name: Me-DGIC, 30 wt % propylene glycol monomethyl ether solution), 1.33 g of 1,6-bis(2,3-epoxypropane-1-yloxy)naphthalene (manufactured by DIC Corporation, trade name: HP-4032D), 1.96 g of (+)-camphoric acid, 0.24 g of tetrabutylphosphonium bromide, and 16.10 g of propylene glycol monomethyl ether were added, and the mixture was heated and stirred under a nitrogen atmosphere at an internal temperature of 105° C. for 24 hours. The obtained reaction product corresponded to Formula (1-2), and the weight average molecular weight Mw measured in terms of polystyrene by GPC was 9200.

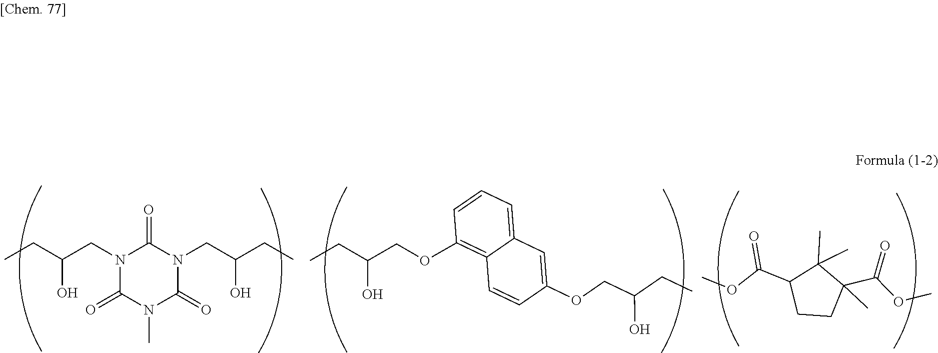

### Synthesis Example 3

Into a reaction flask, 4.00 g of monomethyl diglycidyl isocyanuric acid (manufactured by SHIKOKU CHEMICALS CORPORATION, product name: Me-DGIC, 30 wt % propylene glycol monomethyl ether solution), 1.33 g of 1,6-bis(2,3-epoxypropane-1-yloxy)naphthalene (manufactured by DIC Corporation, trade name: HP-4032D), 1.70 g of trans-1,4-cyclohexanedicarboxylic acid, 0.24 g of tetrabutylphosphonium bromide, and 15.07 g of propylene glycol monomethyl ether were added, and the mixture was heated and stirred under a nitrogen atmosphere at an internal temperature of 105° C. for 24 hours. The obtained reaction product corresponded to Formula (1-3), and the weight average molecular weight Mw measured in terms of polystyrene by GPC was 8400.

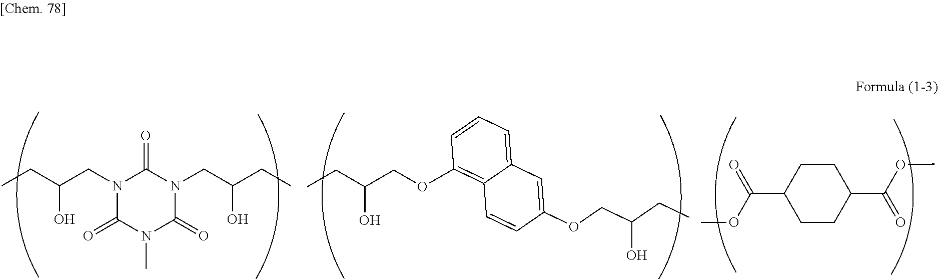

### Synthesis Example 4

Into a reaction flask, 4.00 g of monomethyl diglycidyl isocyanuric acid (manufactured by SHIKOKU CHEMICALS CORPORATION, product name: Me-DGIC, 30 wt % propylene glycol monomethyl ether solution), 1.33 g of 1,6-bis(2,3-epoxypropane-1-yloxy)naphthalene (manufactured by DIC Corporation, trade name: HP-4032D), 1.80 g of 5-norbornene-2,3-dicarboxylic acid, 0.24 g of tetrabutylphosphonium bromide, and 15.47 g of propylene glycol monomethyl ether were added, and the mixture was heated and stirred under a nitrogen atmosphere at an internal temperature of 105° C. for 24 hours. The obtained reaction product corresponded to Formula (1-4), and the weight average molecular weight Mw measured in terms of polystyrene by GPC was 4500.

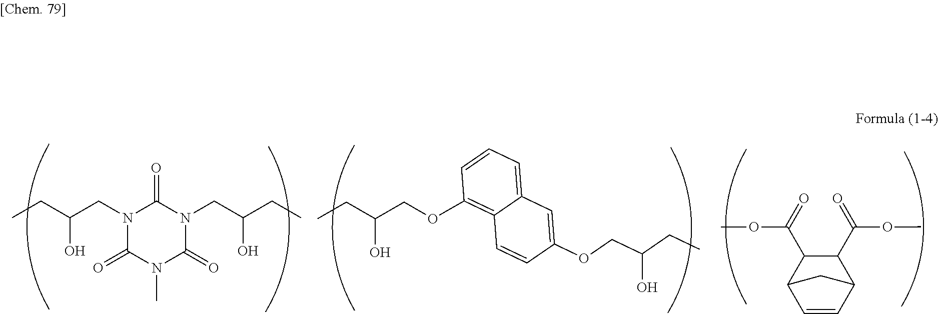

### Synthesis Example 5

Into a reaction flask, 5.00 g of monomethyl diglycidyl isocyanuric acid (manufactured by SHIKOKU CHEMICALS CORPORATION, product name: Me-DGIC, 30 wt % propylene glycol monomethyl ether solution), 1.73 g of terephthalic acid diglycidyl ester (manufactured by Nagase ChemteX Corporation, trade name: DENACOL EX-711), 2.77 g of 1,3-adamantane dicarboxylic acid, 0.30 g of tetrabutylphosphonium bromide, and 21.67 g of propylene glycol monomethyl ether were added, and the mixture was heated and stirred under a nitrogen atmosphere at an internal temperature of 105° C. for 24 hours. The obtained reaction product corresponded to Formula (1-5), and the weight average molecular weight Mw measured in terms of polystyrene by GPC was 8400.

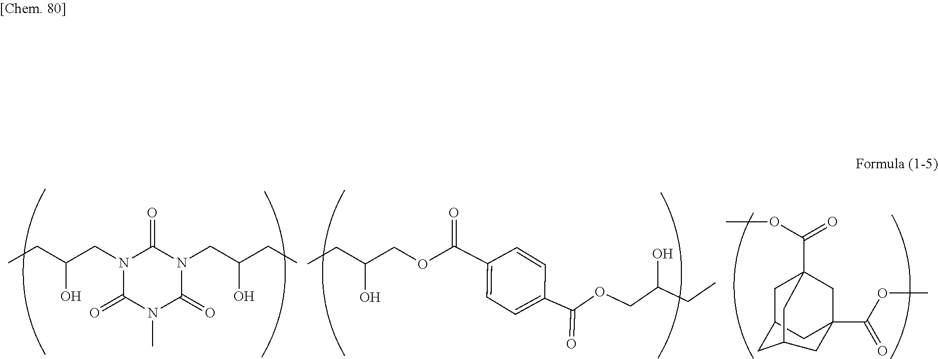

### Synthesis Example 6

Into a reaction flask, 5.00 g of monomethyl diglycidyl isocyanuric acid (manufactured by SHIKOKU CHEMICALS CORPORATION, product name: Me-DGIC, 30 wt % propylene glycol monomethyl ether solution), 2.79 g of resorcinol diglycidyl ether (manufactured by Nagase ChemteX Corporation, trade name: DENACOL EX-201-IM, 50 wt % propylene glycol monomethyl ether solution), 2.77 g of 1,3-adamantane dicarboxylic acid, 0.30 g of tetrabutylphosphonium bromide, and 18.94 g of propylene glycol monomethyl ether were added, and the mixture was heated and stirred under a nitrogen atmosphere at an internal temperature of 105° C. for 24 hours. The obtained reaction product corresponded to Formula (1-6), and the weight average molecular weight Mw measured in terms of polystyrene by GPC was 8700.

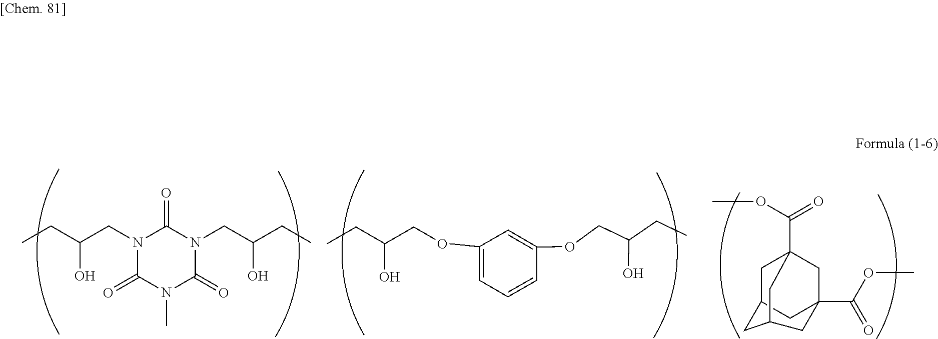

### Synthesis Example 7

Into a reaction flask, 4.00 g of monomethyl diglycidyl isocyanuric acid (manufactured by SHIKOKU CHEMICALS CORPORATION, product name: Me-DGIC, 30 wt % propylene glycol monomethyl ether solution), 1.93 g of naphthalene-type epoxy resin (manufactured by DIC Corporation, trade name: HP-4770), 2.53 g of 1,3-adamantane dicarboxylic acid, 0.24 g of tetrabutylphosphonium bromide, and 20.79 g of propylene glycol monomethyl ether were added, and the mixture was heated and stirred under a nitrogen atmosphere at an internal temperature of 105° C. for 24 hours. The obtained reaction product corresponded to Formula (1-7), and the weight average molecular weight Mw measured in terms of polystyrene by GPC was 9800.

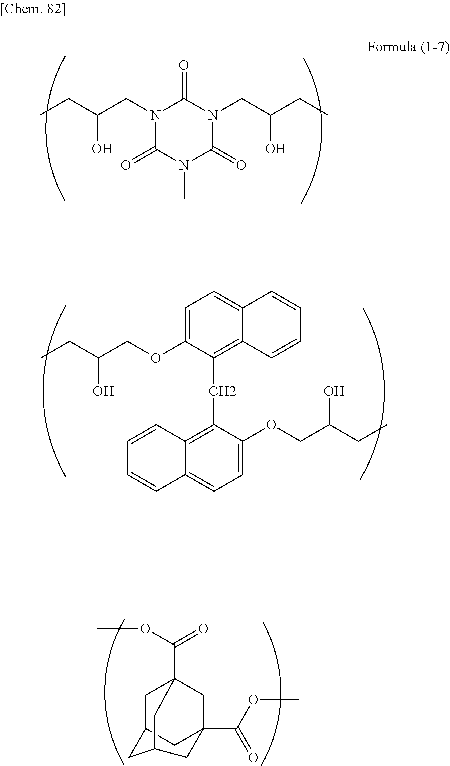

### Synthesis Example 8

Into a reaction flask, 7.00 g of monomethyl diglycidyl isocyanuric acid (manufactured by SHIKOKU CHEMICALS CORPORATION, product name: Me-DGIC, 30 wt % propylene glycol monomethyl ether solution), 1.64 g of 1,3-adamantane dicarboxylic acid, 1.64 g of bis(4-hydroxyphenyl) sulfone, 0.21 g of tetrabutylphosphonium bromide, and 12.56 g of propylene glycol monomethyl ether were added, and the mixture was heated and stirred under a nitrogen atmosphere at an internal temperature of 105° C. for 24 hours. The obtained reaction product corresponded to Formula (1-8), and the weight average molecular weight Mw measured in terms of polystyrene by GPC was 5200.

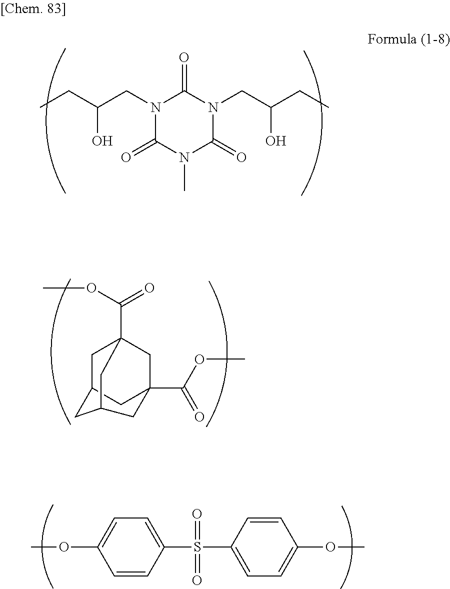

### Synthesis Example 9

Into a reaction flask, 7.00 g of diglycidyl dimethylhydantoin (manufactured by SHIKOKU CHEMICALS CORPORATION, product name: DG-DMH, 30 wt % propylene glycol monomethyl ether solution), 0.81 g of 5-hydroxyisophthalic acid, 1.10 g of 1,3-adamantane dicarboxylic acid, 0.22 g of tetrabutylphosphonium bromide, and 12.00 g of propylene glycol monomethyl ether were added, and the mixture was heated and stirred under a nitrogen atmosphere at an internal temperature of 105° C. for 24 hours. The obtained reaction product corresponded to Formula (1-9), and the weight average molecular weight Mw measured in terms of polystyrene by GPC was 6300.

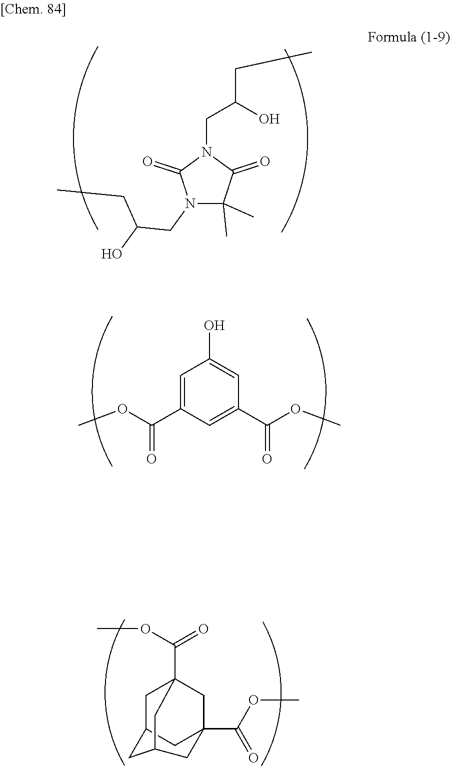

### Comparative Synthesis Example 1

Into a reaction flask, 5.00 g of monomethyl diglycidyl isocyanuric acid (manufactured by SHIKOKU CHEMICALS CORPORATION, product name: Me-DGIC, 30 wt % propylene glycol monomethyl ether solution), 1.66 g of 1,6-bis(2,3-epoxypropane-1-yloxy)naphthalene (manufactured by DIC Corporation, trade name: HP-4032D), 2.19 g of 2,2-thioglycolic acid, 0.30 g of tetrabutylphosphonium bromide, and 19.10 g of propylene glycol monomethyl ether were added, and the mixture was heated and stirred under a nitrogen atmosphere at an internal temperature of 105° C. for 24 hours. The obtained reaction product corresponded to Formula (1-10), and the weight average molecular weight Mw measured in terms of polystyrene by GPC was 1700.

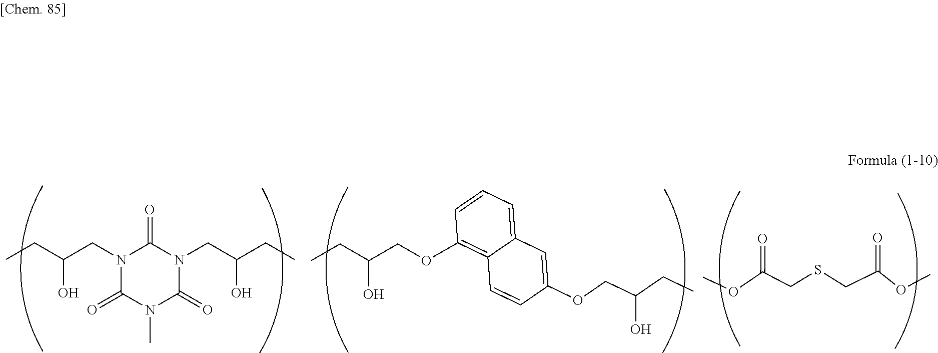

### Comparative Synthesis Example 2

Into a reaction flask, 7.00 g of diglycidyl dimethylhydantoin (manufactured by SHIKOKU CHEMICALS CORPORATION, product name: DG-DMH, 30 wt % propylene glycol monomethyl ether solution), 0.81 g of 5-hydroxyisophthalic acid, 0.72 g of L(+)-tartaric acid, 0.22 g of tetrabutylphosphonium bromide, and 12.00 g of propylene glycol monomethyl ether were added, and the mixture was heated and stirred under a nitrogen atmosphere at an internal temperature of 105° C. for 24 hours. The obtained reaction product corresponded to Formula (1-11), and the weight average molecular weight Mw measured in terms of polystyrene by GPC was 1700.

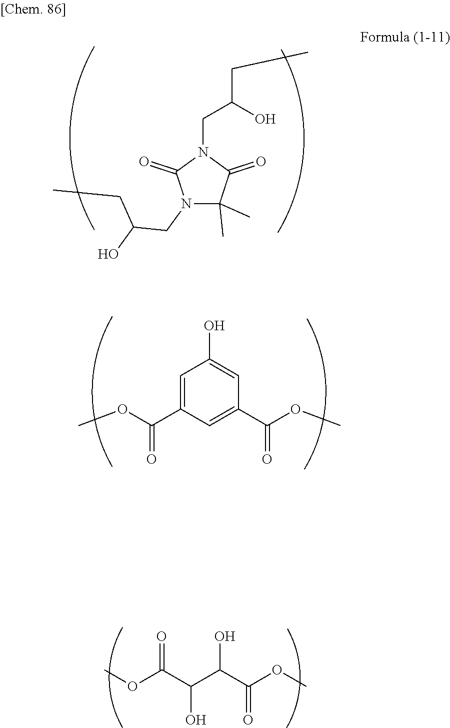

### Example 1

To 2.707 g of a solution (solid content: 17.4 wt %) of the reaction product corresponding to Formula (1-1) obtained in Synthesis Example 1, 0.118 g of tetramethoxymethylglycoluril (trade name: POWDER LINK [registered trademark]1174, manufactured by Nippon Scientific Co., Ltd.) as a crosslinking agent, 0.012 g of pyridinium-p-toluenesulfonate as a crosslinking catalyst, 0.001 g of MEGAFACE R-30N (manufactured by DIC Corporation, trade name), 51.223 g of propylene glycol monomethyl ether, and 5.940 g of propylene glycol monomethyl ether acetate were added to prepare a resist underlayer film-forming composition.

### Example 2

To 2.529 g of a solution (solid content: 18.6 wt %) of the reaction product corresponding to Formula (1-2) obtained in Synthesis Example 2, 0.118 g of tetramethoxymethylglycoluril (trade name: POWDER LINK [registered trademark]1174, manufactured by Nippon Scientific Co., Ltd.) as a crosslinking agent, 0.012 g of pyridinium-p-toluenesulfonate as a crosslinking catalyst, 0.001 g of MEGAFACE R-30N (manufactured by DIC Corporation, trade name), 51.401 g of propylene glycol monomethyl ether, and 5.940 g of propylene glycol monomethyl ether acetate were added to prepare a resist underlayer film-forming composition.

### Example 3

To 2.588 g of a solution (solid content: 18.2 wt %) of the reaction product corresponding to Formula (1-3) obtained in Synthesis Example 3, 0.118 g of tetramethoxymethylglycoluril (trade name: POWDER LINK [registered trademark]1174, manufactured by Nippon Scientific Co., Ltd.) as a crosslinking agent, 0.012 g of pyridinium-p-toluenesulfonate as a crosslinking catalyst, 0.001 g of MEGAFACE R-30N (manufactured by DIC Corporation, trade name), 51.342 g of propylene glycol monomethyl ether, and 5.940 g of propylene glycol monomethyl ether acetate were added to prepare a resist underlayer film-forming composition.

### Example 4

To 2.599 g of a solution (solid content: 18.1 wt %) of the reaction product corresponding to Formula (1-4) obtained in Synthesis Example 4, 0.118 g of tetramethoxymethylglycoluril (trade name: POWDER LINK [registered trademark]1174, manufactured by Nippon Scientific Co., Ltd.) as a crosslinking agent, 0.012 g of pyridinium-p-toluenesulfonate as a crosslinking catalyst, 0.001 g of MEGAFACE R-30N (manufactured by DIC Corporation, trade name), 51.310 g of propylene glycol monomethyl ether, and 5.940 g of propylene glycol monomethyl ether acetate were added to prepare a resist underlayer film-forming composition.

### Example 5

To 2.620 g of a solution (solid content: 18.0 wt %) of the reaction product corresponding to Formula (1-5) obtained in Synthesis Example 5, 0.118 g of tetramethoxymethylglycoluril (trade name: POWDER LINK [registered trademark]1174, manufactured by Nippon Scientific Co., Ltd.) as a crosslinking agent, 0.012 g of pyridinium-p-toluenesulfonate as a crosslinking catalyst, 0.001 g of MEGAFACE R-30N (manufactured by DIC Corporation, trade name), 51.311 g of propylene glycol monomethyl ether, and 5.940 g of propylene glycol monomethyl ether acetate were added to prepare a resist underlayer film-forming composition.

### Example 6

To 2.542 g of a solution (solid content: 18.5 wt %) of the reaction product corresponding to Formula (1-6) obtained in Synthesis Example 6, 0.118 g of tetramethoxymethylglycoluril (trade name: POWDER LINK [registered trademark]1174, manufactured by Nippon Scientific Co., Ltd.) as a crosslinking agent, 0.012 g of pyridinium-p-toluenesulfonate as a crosslinking catalyst, 0.001 g of MEGAFACE R-30N (manufactured by DIC Corporation, trade name), 51.389 g of propylene glycol monomethyl ether, and 5.940 g of propylene glycol monomethyl ether acetate were added to prepare a resist underlayer film-forming composition.

### Example 7

To 2.405 g of a solution (solid content: 19.6 wt %) of the reaction product corresponding to Formula (1-7) obtained in Synthesis Example 7, 0.118 g of tetramethoxymethylglycoluril (trade name: POWDER LINK [registered trademark]1174, manufactured by Nippon Scientific Co., Ltd.) as a crosslinking agent, 0.012 g of pyridinium-p-toluenesulfonate as a crosslinking catalyst, 0.001 g of MEGAFACE R-30N (manufactured by DIC Corporation, trade name), 51.525 g of propylene glycol monomethyl ether, and 5.940 g of propylene glycol monomethyl ether acetate were added to prepare a resist underlayer film-forming composition.

### Example 8

To 2.538 g of a solution (solid content: 18.5 wt %) of the reaction product corresponding to Formula (1-8) obtained in Synthesis Example 8, 0.118 g of tetramethoxymethylglycoluril (trade name: POWDER LINK [registered trademark]1174, manufactured by Nippon Scientific Co., Ltd.) as a crosslinking agent, 0.012 g of pyridinium-p-toluenesulfonate as a crosslinking catalyst, 0.001 g of MEGAFACE R-30N (manufactured by DIC Corporation, trade name), 51.393 g of propylene glycol monomethyl ether, and 5.940 g of propylene glycol monomethyl ether acetate were added to prepare a resist underlayer film-forming composition.

### Example 9

To 2.458 g of a solution (solid content: 19.1 wt %) of the reaction product corresponding to Formula (1-9) obtained in Synthesis Example 9, 0.118 g of tetramethoxymethylglycoluril (trade name: POWDER LINK [registered trademark]1174, manufactured by Nippon Scientific Co., Ltd.) as a crosslinking agent, 0.012 g of pyridinium-p-toluenesulfonate as a crosslinking catalyst, 0.001 g of MEGAFACE R-30N (manufactured by DIC Corporation, trade name), 51.472 g of propylene glycol monomethyl ether, and 5.940 g of propylene glycol monomethyl ether acetate were added to prepare a resist underlayer film-forming composition.

### Comparative Example 1

To 3.584 g of a solution (solid content: 13.1 wt %) of the reaction product corresponding to Formula (1-10) obtained in Comparative Synthesis Example 1, 0.118 g of tetramethoxymethylglycoluril (trade name: POWDER LINK [registered trademark]1174, manufactured by Nippon Scientific Co., Ltd.) as a crosslinking agent, 0.012 g of pyridinium-p-toluenesulfonate as a crosslinking catalyst, 0.001 g of MEGAFACE R-30N (manufactured by DIC Corporation, trade name), 50.346 g of propylene glycol monomethyl ether, and 5.940 g of propylene glycol monomethyl ether acetate were added to prepare a resist underlayer film-forming composition.

### Comparative Example 2

To 2.305 g of a solution (solid content: 20.4 wt %) of the reaction product corresponding to Formula (1-11) obtained in Comparative Synthesis Example 2, 0.118 g of tetramethoxymethylglycoluril (trade name: POWDER LINK [registered trademark]1174, manufactured by Nippon Scientific Co., Ltd.) as a crosslinking agent, 0.012 g of pyridinium-p-toluenesulfonate as a crosslinking catalyst, 0.001 g of MEGAFACE R-30N (manufactured by DIC Corporation, trade name), 51.625 g of propylene glycol monomethyl ether, and 5.940 g of propylene glycol monomethyl ether acetate were added to prepare a resist underlayer film-forming composition.

### [Evaluation of Resist Solvent Resistance]

Each of the resist underlayer film-forming compositions prepared in Examples 1 to 9 and Comparative Examples 1 to 2 was applied (used in spin-coating) onto a silicon wafer with a spin coater. The silicon wafer after the application was heated on a hot plate at 215° C. for 1 minute to form a resist underlayer film having a film thickness of 20 nm. Next, for confirming the resist solvent resistance of the resist underlayer film, the silicon wafer after formation of the resist underlayer film was immersed for 1 minute in a solvent in which propylene glycol monomethyl ether and propylene glycol monomethyl ether acetate were mixed at a weight ratio of 7: 3, spin-dried, and then baked at 100° C. for 30 seconds. The film thickness of the resist underlayer film was measured before and after immersion in the mixed solvent with a film thickness measuring apparatus (product name: RE-3100, manufactured by Dainippon Screen Mfg. Co., Ltd.).

From the following calculation formula, the resist solvent resistance was evaluated by calculating the resist underlayer film thickness reduction rate (%) resulting from removal by solvent immersion. Table 1 shows the results. If the film thickness reduction rate is about 1% or less, it can be said that the film has sufficient resist solvent resistance.

Film thickness reduction rate (%)=[(A₀−A₁)+A₀]×100
A₀: Film thickness before solvent immersion
A₁: Film thickness after solvent immersion

TABLE 1

| | Film thickness reduction rate |
|---|---|
| Example 1 | −0.50% |
| Example 2 | −0.30% |
| Example 3 | −0.20% |
| Example 4 | 0.00% |
| Example 5 | −0.40% |
| Example 6 | −0.20% |
| Example 7 | −0.50% |
| Example 8 | −0.20% |
| Example 9 | 0.50% |
| Comparative Example 1 | 0.00% |
| Comparative Example 2 | 0.30% |

From the above results, the resist underlayer film-forming compositions of Examples 1 to 9 and Comparative Examples 1 to 2 had a very small film thickness change even after immersion in the resist solvent. Therefore, the resist underlayer film-forming compositions of Examples 1 to 9 have sufficient resist solvent resistance to function as a resist underlayer film.

### [Evaluation of Optical Constant]

Each of the resist underlayer film-forming compositions prepared in Examples 1 to 9 and Comparative Examples 1 to 2 was applied onto a silicon wafer with a spin coater so as to have a film thickness of about 50 nm, and baked (fired) on a hot plate at 215° C. for 60 seconds. For the obtained resist underlayer film, the n value (refractive index) and the k value (attenuation coefficient) at a wavelength of 193 nm (ArF excimer laser light wavelength) were measured using a spectroscopic ellipsometer (VUV-VASE, manufactured by J. A. Woolam). Table 2 shows the results.

TABLE 2

| | n/k(193 nm) |
|---|---|
| Example 1 | 1.73/0.12 |
| Example 2 | 1.72/0.13 |
| Example 3 | 1.73/0.14 |
| Example 4 | 1.69/0.21 |
| Example 5 | 1.75/0.21 |
| Example 6 | 1.72/0.19 |
| Example 7 | 1.69/0.12 |
| Example 8 | 1.84/0.22 |
| Example 9 | 1.73/0.17 |
| Comparative Example 1 | 1.78/0.17 |
| Comparative Example 2 | 1.72/0.17 |

From the above results, in Examples 1 to 9, the resist underlayer film has an n value and a k value appropriate at 193 nm. Therefore, the coating film obtained from the resist underlayer film-forming composition obtained in each of Examples 1 to 9 has an anti-reflective function so as to be capable of suppressing reflection (standing wave), which may cause an unfavorable resist pattern, from a base substrate in a lithography process in which a radiation of an ArF excimer laser or the like is used. Therefore, the coating film is useful as a resist underlayer film.

### [Formation and Evaluation of Resist Pattern]

Each of the resist underlayer film-forming compositions prepared in Examples and Comparative Examples was evaluated for lithographic performance by negative development (NTD).

A silicon wafer was spin-coated with a composition for an anti-reflective layer for reflection control, and heated at 205° C. for 1 minute to form an anti-reflective layer (n=1.81, k=0.33, 193 nm). Next, the anti-reflective layer was spin-coated with each of the resist underlayer film-forming compositions prepared in Examples 1 to 9 and Comparative Examples 1 to 2, and heated at 215° C. for 1 minute to form a resist underlayer film. The resist underlayer film was spin-coated with a resist solution for NTD, heated at 90° C. for 60 seconds, and exposed under a predetermined condition using an exposure apparatus for an ArF excimer laser (NSR-307E manufactured by NIKON CORPORATION). After the exposure, the resulting product was heated (PEB) at 90° C. for 60 seconds, cooled to room temperature on a cooling plate, and developed with n-butyl acetate to form a line/space resist pattern.

The dimension of the formed resist pattern was measured with a length measurement SEM. Table 3 below summarizes the minimum line CD (Min Line CD) obtained by exposure to various amounts of light.

TABLE 3

| | Min Line CD [nm] |
|---|---|
| Example 1 | 34.65 |
| Example 2 | 34.24 |
| Example 3 | 36.25 |
| Example 4 | 38.80 |
| Example 5 | 38.80 |
| Example 6 | 37.58 |
| Example 7 | 39.61 |
| Example 8 | 36.69 |
| Example 9 | 34.16 |
| Comparative Example 1 | 40.03 |
| Comparative Example 2 | 40.07 |

From the above results, it can be said that the Min Line CD is more improved in the resist underlayer film-forming compositions of Examples 1 to 9 than in the resist underlayer film-forming compositions of Comparative Examples 1 to 2. That is, introduction of an alicyclic structure into the resist underlayer film develops adhesion to the resist, and an undesirable phenomenon of resist pattern collapse can be suppressed.

1. A resist underlayer film-forming composition comprising: a polymer having an alicyclic structure in a portion other than a terminal; and a solvent.

2. The resist underlayer film-forming composition according to claim 1, wherein the polymer further has an aromatic hydrocarbon ring.

3. The resist underlayer film-forming composition according to claim 1, wherein the polymer further has a nitrogen-containing ring.

4. The resist underlayer film-forming composition according to claim 1, wherein the polymer has a structure having the alicyclic structure, the structure represented by Formula (1) described below: 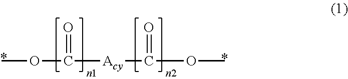
wherein A_{cy} represents a divalent group having the alicyclic structure, n1 and n2 each independently represent 0 or 1, and * represents a bond.

5. The resist underlayer film-forming composition according to claim 2, wherein the polymer has a structure having the aromatic hydrocarbon ring, the structure represented by Formula (2) described below: 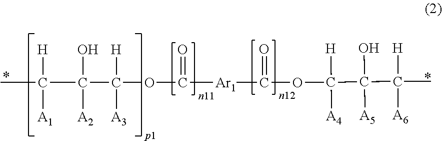
wherein Ar₁ represents a divalent organic group having the aromatic hydrocarbon ring, n11 and n12 each independently represent 0 or 1, p1 and p2 each independently represent 0 or 1, A₁, A₂, A₃, A₄, A₅, and A₆ each independently represent a hydrogen atom, a methyl group, or an ethyl group, and * represents a bond.

6. The resist underlayer film-forming composition according to claim 3, wherein the polymer has a structure having the nitrogen-containing ring, the structure represented by Formula (3) described below: 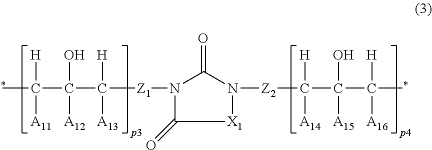
wherein X₁ represents a group represented by any one of Formulas (3-1) to (3-3) described below: 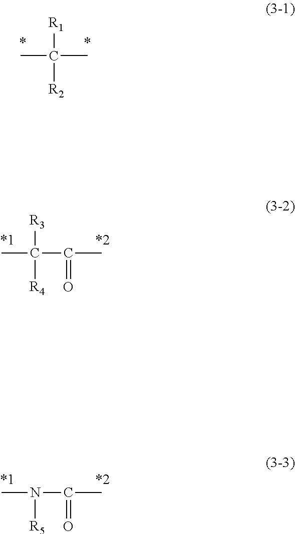
wherein R₁ to R₅ each independently represent a hydrogen atom, an alkyl group having 1 to 10 carbon atoms that are optionally interrupted by an oxygen atom or a sulfur atom, an alkenyl group having 2 to 10 carbon atoms that are optionally interrupted by an oxygen atom or a sulfur atom, an alkynyl group having 2 to 10 carbon atoms that are optionally interrupted by an oxygen atom or a sulfur atom, a benzyl group, or a phenyl group, and the phenyl group is optionally substituted with at least one monovalent group selected from the group consisting of alkyl groups having 1 to 6 carbon atoms, halogen atoms, alkoxy groups having 1 to 6 carbon atoms, a nitro group, a cyano group, and alkylthio groups having 1 to 6 carbon atoms,
R₁ and R₂ are optionally bonded to each other to form a ring having 3 to 6 carbon atoms,
R₃ and R₄ are optionally bonded to each other to form a ring having 3 to 6 carbon atoms,
* represents a bond, *1 represents a bond to a carbon atom in Formula (3), and *2 represents a bond to a nitrogen atom in Formula (3),
Z₁ and Z₂ each independently represent a single bond or a divalent group represented by Formula (3-4) described below: 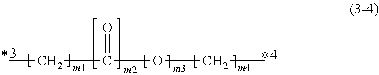
wherein m1 is an integer of 0 to 4, m2 is 0 or 1, m3 is 0 or 1, and m4 is an integer of 0 to 2 while m1 and m2 are not simultaneously 0 in a case where m3 is 1, *3 represents a bond to a nitrogen atom in Formula (3), and *4 represents a bond,
A₁₁, A₁₂, A₁₃, A₁₄, A₁₅, and A₁₆ each independently represent a hydrogen atom, a methyl group, or an ethyl group, p3 and p4 each independently represent 0 or 1, and * represents a bond.

7. The resist underlayer film-forming composition according to claim 1, further comprising a crosslinking agent.

8. The resist underlayer film-forming composition according to claim 1, further comprising a curing catalyst.

9. The resist underlayer film-forming composition according to claim 1, being a resist underlayer film-forming composition for formation of an underlayer of a negative photoresist.

10. The resist underlayer film-forming composition according to claim 1, being a resist underlayer film-forming composition for photolithography using an ArF excimer laser or extreme ultraviolet (EUV).

11. A resist underlayer film consisting of a cured product of the resist underlayer film-forming composition according to claim 1.

12. A semiconductor processing substrate comprising:
a semiconductor substrate; and
the resist underlayer film according to claim 11.

13. A method of manufacturing a semiconductor element,
the method comprising the steps of:
forming a resist underlayer film on a semiconductor substrate using the resist underlayer film-forming composition according to claim 1; and
forming a resist film on the resist underlayer film.

14. A method of forming a pattern, the method comprising the steps of:
forming a resist underlayer film on a semiconductor substrate using the resist underlayer film-forming composition according to claim 1;
forming a resist film on the resist underlayer film;
irradiating the resist film with light or an electron beam and then developing the resist film to obtain a resist pattern; and
etching the resist underlayer film using the resist pattern as a mask.
